(19) United States
(12) Patent Application Publication
(10) Pub. No.: US 2024/0404889 A1
(43) Pub. Date: Dec. 5, 2024

(54) SEMICONDUCTOR DEVICE AND METHODS OF FORMATION

(71) Applicant: Taiwan Semiconductor Manufacturing Compant, Ltd., Hsinchu (TW)

(72) Inventors: Shih-Sian TU, Tainan City (TW); Yu-Jen CHEN, Tainan City (TW); Jhen-Wei CHEN, Tainan City (TW)

(21) Appl. No.: 18/327,491

(22) Filed: Jun. 1, 2023

(51) Int. Cl. H01L 21/8238; H01L 27/092; H01L 29/66

(52) U.S. Cl. CPC H01L 21/823878; H01L 21/823821; H01L 27/0924; H01L 29/66545

(57) ABSTRACT

A non-active gate structure is formed over a shallow trench isolation (STI) region that is adjacent to at least one fin structure of a semiconductor device that includes a fin-based transistor. The non-active gate structure includes at least one support structure that extends from the gate in a direction that is approximately orthogonal to the direction in which the main body of the non-active gate structure extends. The support structure provides structural support for the non-active gate structure, which increases the stability of the non-active gate structure relative to a gate structure that does not include the support structure.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain regions (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A-3D are diagrams of an example implementation of forming a semiconductor device described herein.

FIGS. 4A-4K are diagrams of an example implementation of forming a semiconductor device described herein.

FIGS. 5A-5E are diagrams of an example implementation of forming a semiconductor device described herein.

FIGS. 6A-6C are diagrams of an example implementation of forming a semiconductor device described herein.

FIGS. 7A and 7B are diagrams of example implementations of a semiconductor device described herein.

FIGS. 8A-8D are diagrams of example implementations of a semiconductor device described herein.

FIGS. 9A-9D are diagrams of example implementations of a semiconductor device described herein.

FIG. 10 is a diagram of example components of a device described herein.

FIG. 11 is a flowchart of example processes associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As dimensions such as fin-to-fin spacing and gate length (also referred to as poly critical dimension (CD)) are reduced in the advancement of semiconductor manufacturing processes for fin-based semiconductor devices, various processing challenges may result. For example, reducing the length of gate structures in a fin-based transistor may result in an increased aspect ratio of a thickness to the length of the gate structures. The increased aspect ratio may result in reduced stability for the gate structures, which may result in peeling and collapse of the gate structures. In particular, the greater the aspect ratio, the reduced magnitude of force that may be needed to topple the gate structures. This may result in the gate structures being more susceptible to peeling and collapse, which may increase the likelihood of failures in fin-based transistors included in a semiconductor device.

Gate structures that are included adjacent to fin structures of the fin-based transistor (e.g., that are not included over the fin structures) may be particularly susceptible to peeling and collapse at increased aspect ratios because these gate structures (referred to herein as non-active gate structures) are often included to protect other gate structures (referred to herein as active gate structures) over the fin structures during semiconductor processing of the semiconductor device. The non-active gate structures may be subjected to greater magnitudes of forces relative to the active gate structures, thereby leading to a greater likelihood that the non-active gate structures may experience peeling and collapse.

In some implementations described herein, a non-active gate structure is formed over a shallow trench isolation (STI) region that is adjacent to at least one fin structure of a semiconductor device that includes a fin-based transistor. The non-active gate structure includes at least one support structure that extends from the gate in a direction that is approximately orthogonal to the direction in which the main body of the non-active gate structure extends. The support structure provides structural support for the non-active gate structure, which increases the stability of the non-active gate structure relative to a gate structure that does not include the support structure.

In this way, the support structure reduces a likelihood of peeling and collapse of the non-active gate structure. This reduces the likelihood of formation of defects in the semiconductor device. Moreover, this enables the aspect ratio of the non-active gate structure (e.g., the ratio of the thickness to the length of the non-active gate structure) to be increased without increasing the likelihood of peeling and collapse of the non-active gate structure, which enables the density of gate structures in the semiconductor device to be increased.

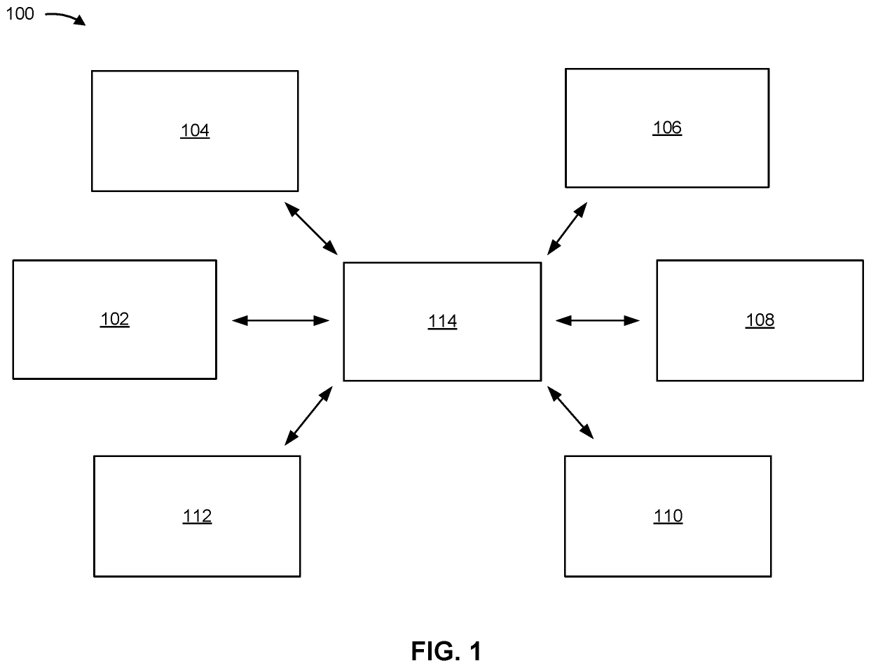

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may perform one or more semiconductor processing operations described herein. For example, one or more of the semiconductor processing tools 102-112 and/or the wafer/die transport tool 114 may forming a plurality of fin structures in a substrate of a semiconductor device, where the plurality of fin structures extend in a first direction in a top-down view of the semiconductor device; may form an STI region on the substrate between the plurality of fin structures and adjacent to ends of the plurality of fin structures, where the plurality of fin structures extend above the STI region; may form one or more dummy gate layers on the STI region and around the plurality of fin structures; may etch the one or more dummy gate layers based on a pattern to form one or more first dummy gate structures that extend in a second direction (y direction), in the top-down view of the semiconductor device, that is approximately perpendicular with the first direction, where the one or more first dummy gate structures wrap around the plurality of fin structures on at least three sides of the plurality of fin structures, and one or more second dummy gate structures that extend in the second direction and are located on the STI region adjacent to ends of the plurality of fin structures, wherein the one or more second dummy gate structures include a main body that extends in the second direction and one or more support structures that extend from the main body in the first direction, among other examples.

As another example, one or more of the semiconductor processing tools 102-112 and/or the wafer/die transport tool 114 may performing a wet cleaning operation after etching the one or more dummy gate layers, where the one or more support structures support the one or more second dummy gate structures during the wet cleaning operation. As another example, one or more of the semiconductor processing tools 102-112 and/or the wafer/die transport tool 114 may performing a wet cleaning operation after etching the one or more dummy gate layers, where the one or more second dummy gate structures protect the one or more first dummy gate structures during the wet cleaning operation. As another example, one or more of the semiconductor processing tools 102-112 and/or the wafer/die transport tool 114 may form, after etching the one or more dummy gate layers, one or more source/drain regions on one or more of the plurality of fin structures; and/or may remove, after forming the one or more source/drain regions, the one or more first dummy gate structures and the one or more second dummy gate structures, where removal of the one or more first dummy gate structures leaves behind one or more first recesses over the plurality of fins, and where removal of the one or more second dummy gate structures leaves behind one or more second recesses over the STI region.

As another example, one or more of the semiconductor processing tools 102-112 and/or the wafer/die transport tool 114 may form, in the one or more first recesses, one or more active gate structures; and/or may form, in the one or more second recesses, one or more non-active gate structures. As another example, one or more of the semiconductor processing tools 102-112 and/or the wafer/die transport tool 114 may form one or more spacer layers on sidewalls of the one or more support structures.

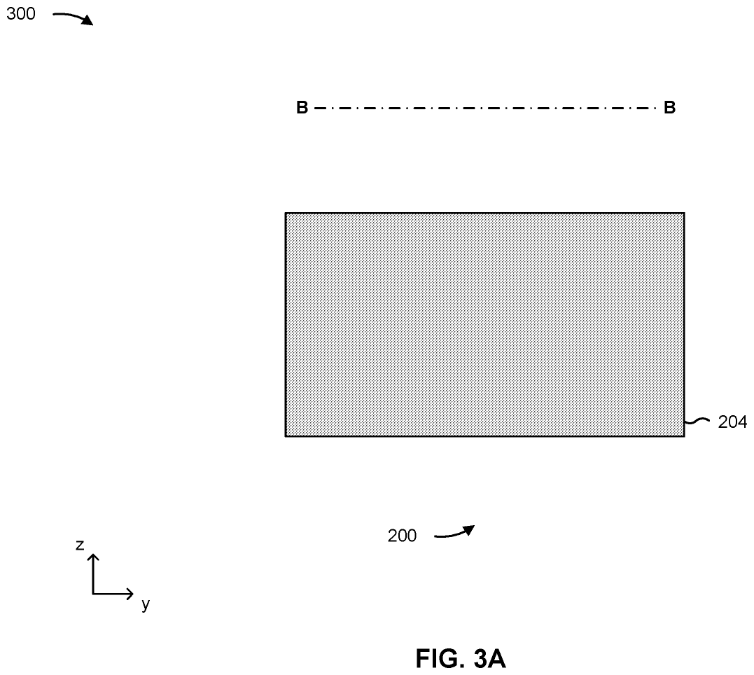

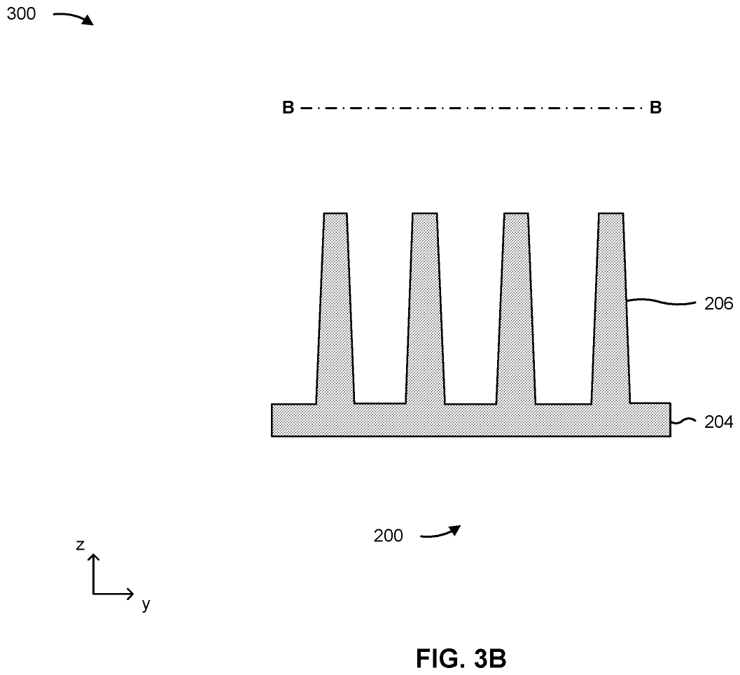

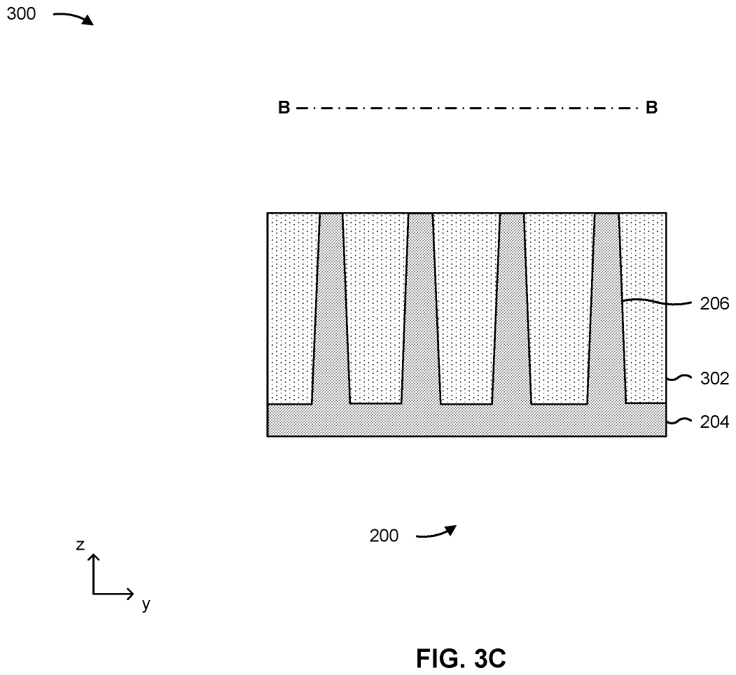

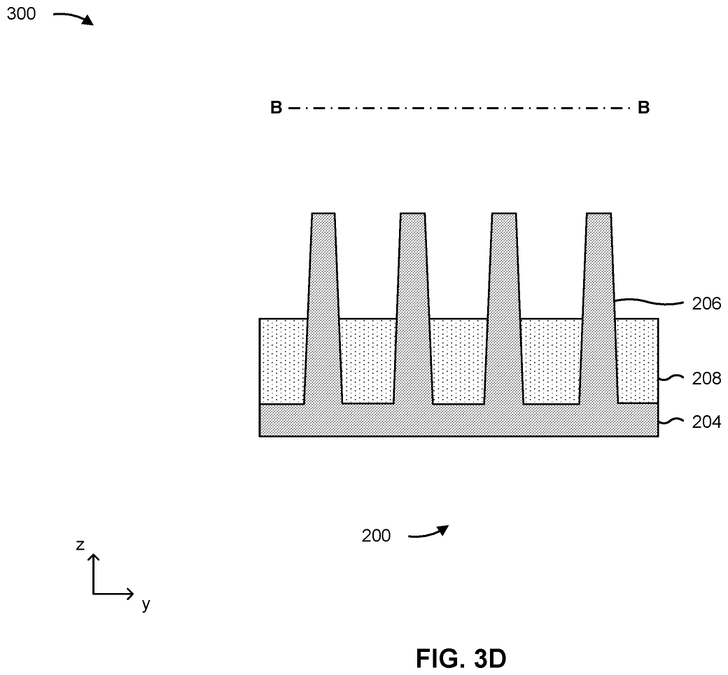

One or more of the semiconductor processing tools 102-112 and/or the wafer/die transport tool 114 may perform other semiconductor processing operations described herein, such as in connection with FIGS. 3A-3D, 4A-4K, 5A-5D, 6A-6C and/or 11, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

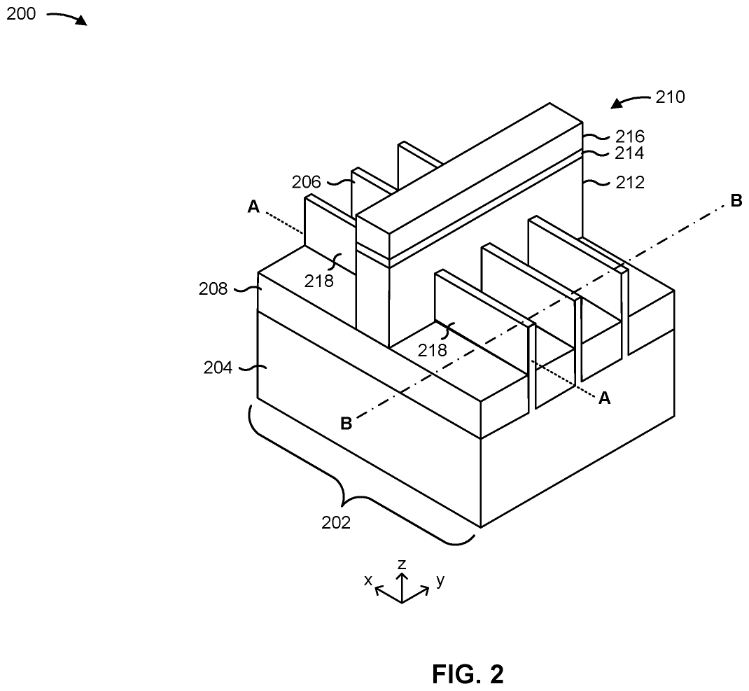

FIG. 2 is a diagram of example regions of a semiconductor device 200 described herein. In particular, FIG. 2 illustrates an example device region 202 of the semiconductor device 200 in which one or more transistors or other devices are included. The transistors may include fin-based transistors, such as fin field effect transistors (finFETs), nanostructure transistors, and/or other types of transistors. In some implementations, the device region 202 includes a p-type metal oxide semiconductor (PMOS) region, an n-type metal oxide semiconductor (NMOS) region, a complementary metal oxide semiconductor (CMOS) region, and/or another type of device region. FIGS. 3A-3D, 4A-4K, 5A-5E, and/or 6A-6C include schematic cross-sectional views of various portions of the device region 202 of the semiconductor device 200 illustrated in FIG. 2, and correspond to various processing stages of forming fin-based transistors in the device region 202 of the semiconductor device 200.

The semiconductor device 200 includes a substrate 204. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate.

Fin structures 206 are included above (and/or extend above) the substrate 204 for the device region 202. A fin structure 206 may provide an active region where one or more devices (e.g., fin-based transistors) are formed. In some implementations, the fin structures 206 include silicon (Si) materials or another elementary semiconductor material such as germanium (Ge). In some implementations, the fin structures 206 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GalInAsP), or a combination thereof. In some implementations, the fin structures 206 are doped using n-type and/or p-type dopants.

The fin structures 206 are fabricated by suitable semiconductor process techniques, such as masking, photolithography, and/or etch processes, among other examples. As an example, the fin structures 206 may be formed by etching a portion of the substrate 204 away to form recesses in the substrate 204. The recesses may then be filled with isolating material that is recessed or etched back to form an STI region 208 above the substrate 204 and between the fin structures 206. Other fabrication techniques for the STI region 208 and/or for the fin structures 206 may be used. The STI region 208 may electrically isolate adjacent active areas in the fin structures 206. The STI region 208 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI region 208 may include a multi-layer structure, for example, having one or more liner layers.

A dummy gate structure 210 (or a plurality of dummy gate structures 210) is included in the device region 202 over the fin structures 206 (e.g., approximately perpendicular to the fin structures 206). The dummy gate structure 210 engages the fin structures 206 on three or more sides of the fin structures 206. In the example depicted in FIG. 2, the dummy gate structure 210 includes a gate electrode layer 212, a hard mask layer 214, and/or a capping layer 216, among other examples. In some implementations, the dummy gate structure 210 further includes a capping layer, one or more spacer layers, and/or another suitable layer. The various layers of the dummy gate structure 210 may be formed by suitable deposition techniques and patterned by suitable photolithography and etching techniques.

The term, “dummy”, as described here, refers to a sacrificial structure which will be removed in a later stage and will be replaced with another structure, such as a high dielectric constant (high-k) dielectric and metal gate structure in a replacement gate process. The replacement gate process refers to manufacturing a gate structure at a later stage of the overall gate manufacturing process. Accordingly, the configuration of the semiconductor device 200 illustrated in FIG. 2 may include an intermediate configuration, and additional semiconductor processing operations may be performed for the semiconductor device 200 to further process the semiconductor device 200.

The gate electrode layer 212 may include a polysilicon (PO) material or another suitable material. The gate electrode layer 212 may be formed by suitable deposition processes such as LPCVD or PECVD, among other examples. The hard mask layer 214 may include any material suitable (e.g., a silicon nitride (SiₓN_{y} such as Si₃N₄) to pattern the gate electrode layer 212 with particular features/dimensions. The capping layer 216 may include a dielectric oxide layer such as a silicon oxide (SiOₓ such as SiO₂). The dielectric oxide layer may be formed by chemical oxidation, thermal oxidation, ALD, CVD, and/or other suitable methods.

In some implementations, the various layers of the dummy gate structure 210 are first deposited as blanket layers. Then, the blanket layers are patterned through a process including photolithography and etching processes, removing portions of the blanket layers and keeping the remaining portions over the STI region 208 and the fin structures 206 to form the dummy gate structure 210.

Source/drain areas 218 are disposed in opposing regions of the fin structures 206 with respect to the dummy gate structure 210. The source/drain areas 218 include areas in the device region 202 in which source/drain regions are to be formed. Source/drain region(s) may refer to a source or a drain, individually or collectively dependent upon the context. The source/drain regions in the device region 202 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the device region 202 may include PMOS transistors that include p-type source/drain regions, NMOS transistors that include n-type source/drain regions, and/or other types of transistors.

Some source/drain regions may be shared between various transistors in the device region 202. In some implementations, various ones of the source/drain regions may be connected or coupled together such that fin-based transistors in the device region 202 are implemented as two functional transistors. For example, if neighboring (e.g., as opposed to opposing) source/drain regions are electrically connected, such as through coalescing the regions by epitaxial growth (e.g., neighboring source/drain regions, as opposed to on opposing sides of the dummy gate structure 210, being coalesced), two functional transistors may be implemented. Other configurations in other examples may implement other numbers of functional transistors.

FIG. 2 further illustrates reference cross-sections that are used in later figures, including FIGS. 3A-3D, 4A-4K, 5A-5D, and/or 6A-6C, among other examples. Cross-section A-A is in a plane along a channel in a fin structure 206 between opposing source/drain areas 218. Cross-section B-B is in a plane perpendicular to cross-section A-A, and is across a source/drain area 218 in fin structure 206. Subsequent figures refer to these reference cross-sections for clarity. In some figures, some reference numbers of components or features illustrated therein may be omitted to avoid obscuring other components or features for ease of depicting the figures.

As described herein, in some implementations, the semiconductor device 200 may include one or more fin structures 206 extending above the substrate 204, the one or more fin structures 206 extend in a first direction (e.g., the x direction) in a top-down view of the semiconductor device 200; may include an active gate structure (that replaces a dummy gate structure 210) that wraps around the one or more fin structures 206 on at least three sides of the one or more fin structures 206, where the active gate structure extends in a second direction (e.g., the y direction), in the top-down view of the semiconductor device 200, that is approximately perpendicular with the first direction; may include a non-active gate structure (that replaces another dummy gate structure 210) on the STI region 208, where the non-active gate structure is adjacent to ends of the one or more fin structures 206, and where the non-active gate structure includes a main body that extends in the second direction and one or more support structures that extend from the main body in the first direction.

As indicated above, FIG. 2 is provided as an example. Other examples may differ from what is described with regard to FIG. 2.

FIGS. 3A-3D are diagrams of an example implementation 300 described herein. The example implementation 300 includes an example of forming fin structures 206 for transistors in the device region 202 of the semiconductor device 200. FIGS. 3A-3D are illustrated from the perspective of the cross-sectional plane B-B in FIG. 2 for the device region 202. Turning to FIG. 3A, the example implementation 300 includes semiconductor processing operations relating to the substrate 204 in and/or on which transistors are formed in the device region 202.

As shown in FIG. 3B, the fin structures 206 are formed in the substrate 204 in the device region 202. In some implementations, a pattern in a photoresist layer is used to form the fin structures 206. In these implementations, the deposition tool 102 forms the photoresist layer on the substrate 204. The exposure tool 104 exposes the photoresist layer to a radiation source to pattern the photoresist layer. The developer tool 106 develops and removes portions of the photoresist layer to expose the pattern. The etch tool 108 etches into the substrate 204 to form the fin structures 206. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the fin structures 206 based on a pattern.

As shown in FIG. 3C, an STI layer 302 is formed in between the fin structures 206. The deposition tool 102 deposits the STI layer 302 using a CVD technique, a PVD technique, an ALD technique, a deposition technique described above in connection with FIG. 1, and/or another deposition technique. In some implementations, the STI layer 302 is formed to a height that is greater than the height of the fin structures 206. In these implementations, the planarization tool 110 performs a planarization (or polishing) operation to planarize the STI layer 302 such that the top surface of the STI layer 302 is substantially flat and smooth, and such that the top surface of the STI layer 302 and the top surface of the fin structures 206 are approximately the same height. The planarization operation may increase uniformity in the STI regions 208 that are formed from the STI layer 302 in a subsequent etch-back operation.

As shown in FIG. 3D, the STI layer 302 is etched in an etch back operation to expose portions of the fin structures 206. The etch tool 108 etches a portion of the STI layer 302 using a plasma etch technique, a wet chemical etch technique, and/or another type of etch technique. The remaining portion of the STI layer 302 between the fin structures 206 include the STI region 208. In some implementations, the STI layer 302 is etched such that the height of the exposed portions of the fin structures 206 (e.g., the portions of the fin structures 206 that are above the top surface of the STI region 208) and the same height in the device region 202. In some implementations, a first portion of the STI layer 302 in the device region 202 is etched and a second portion of the STI layer 302 in the device region 202 is etched such that the height of exposed portions of a first subset of the fin structures 206 and the height of the exposed portions of a second subset of the fin structures 206 are different, which enables the fin heights to be tuned to achieve particular performance characteristics for the device region 202.

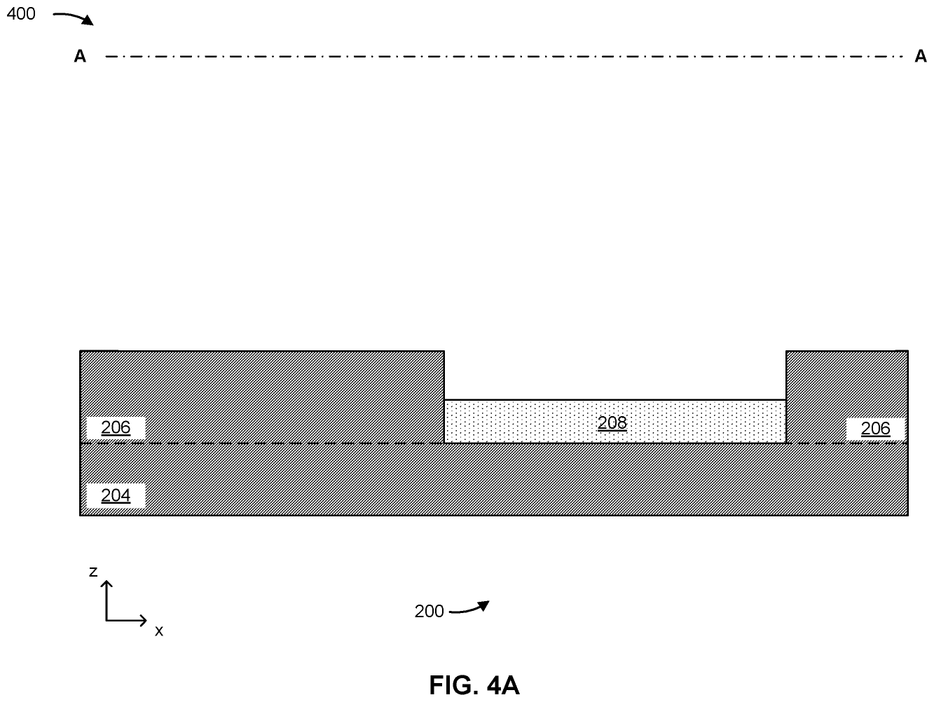

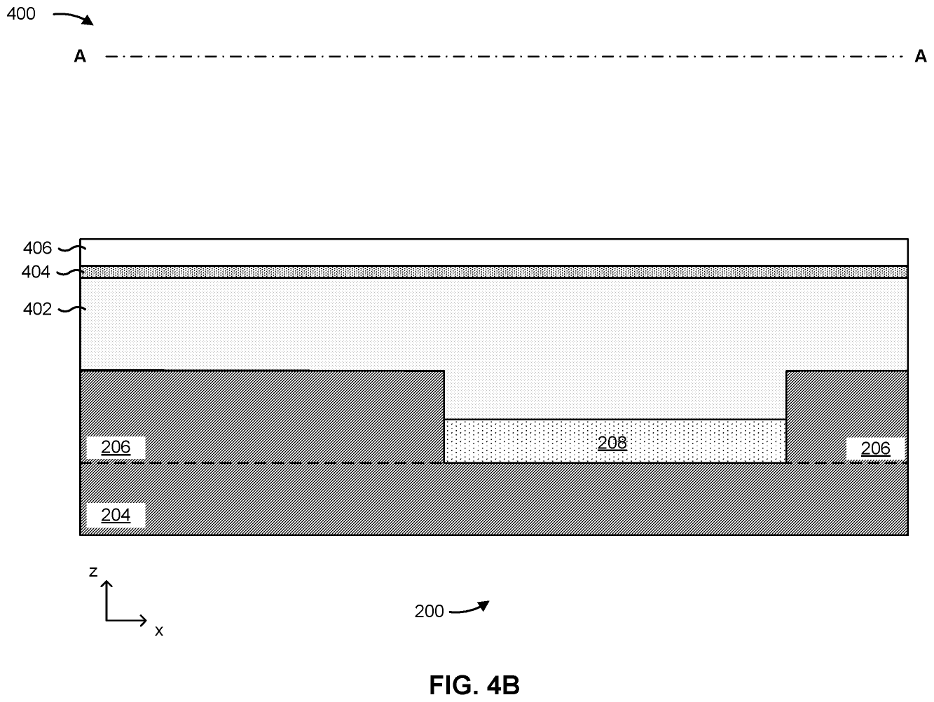

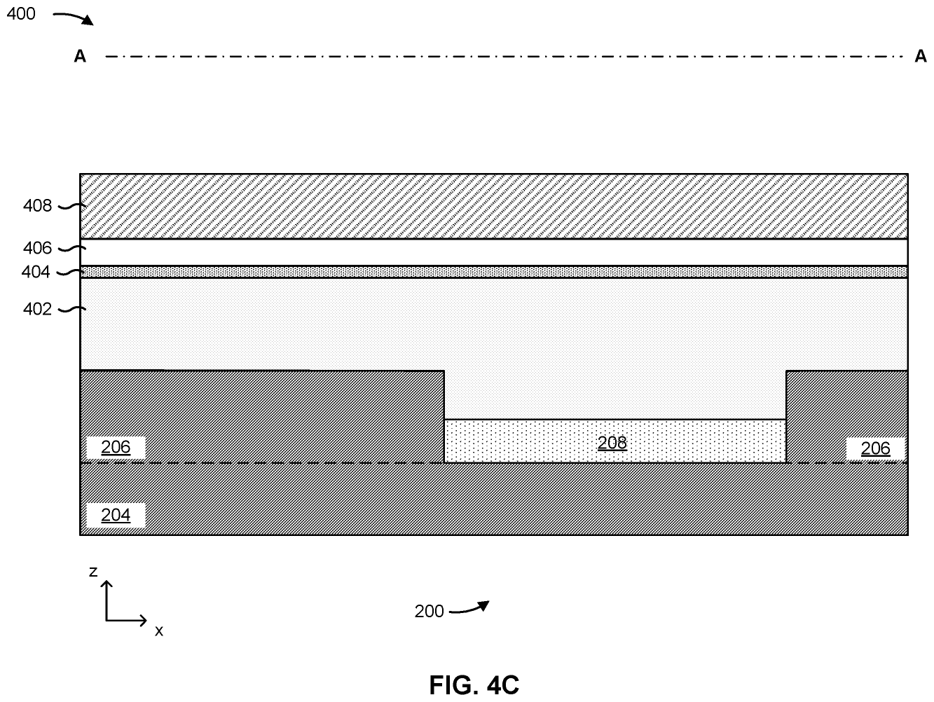

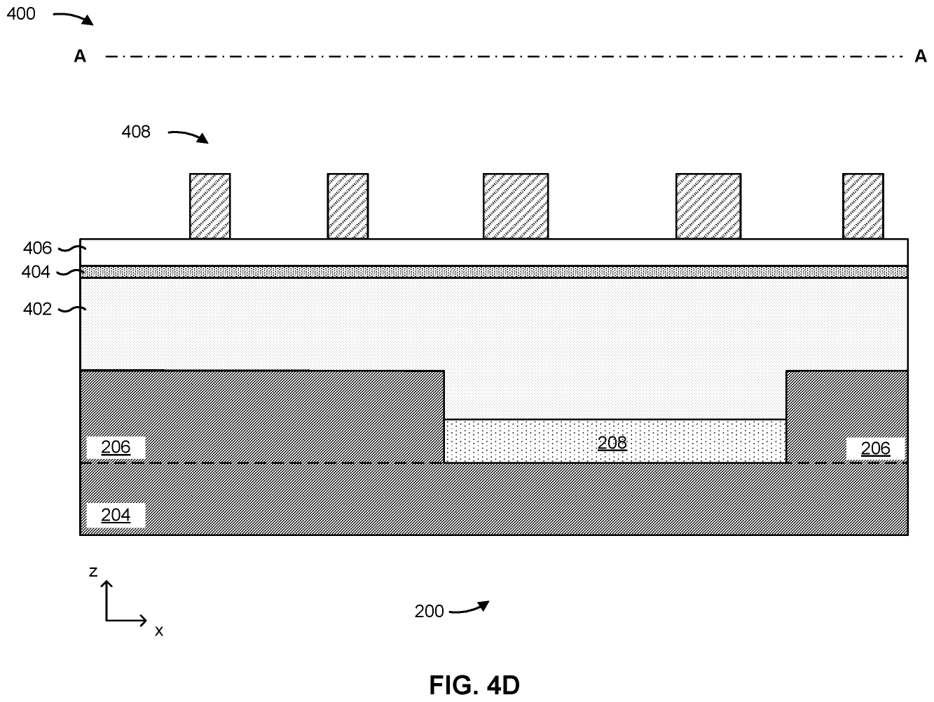

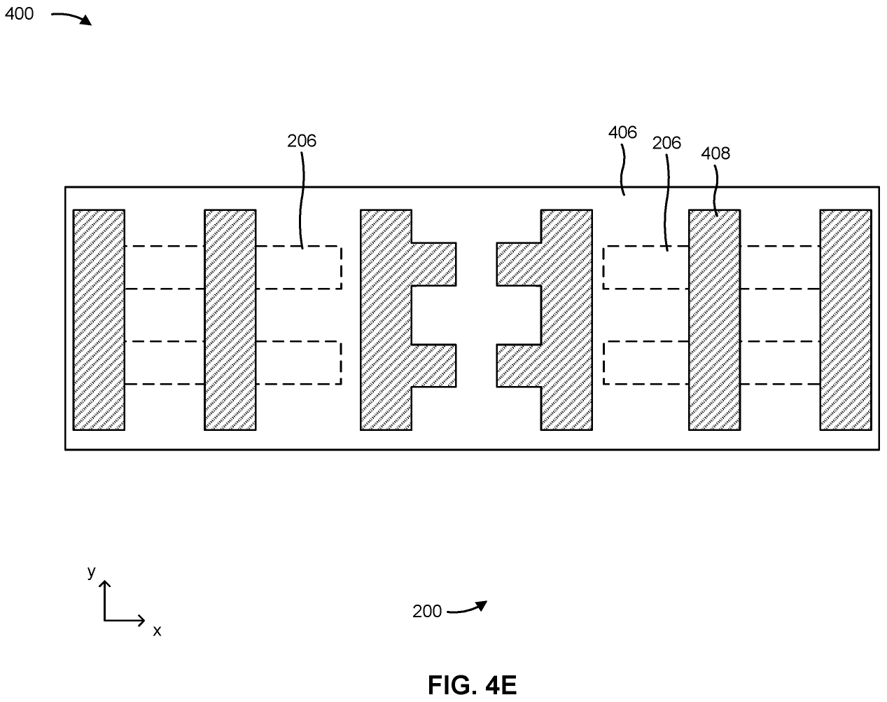

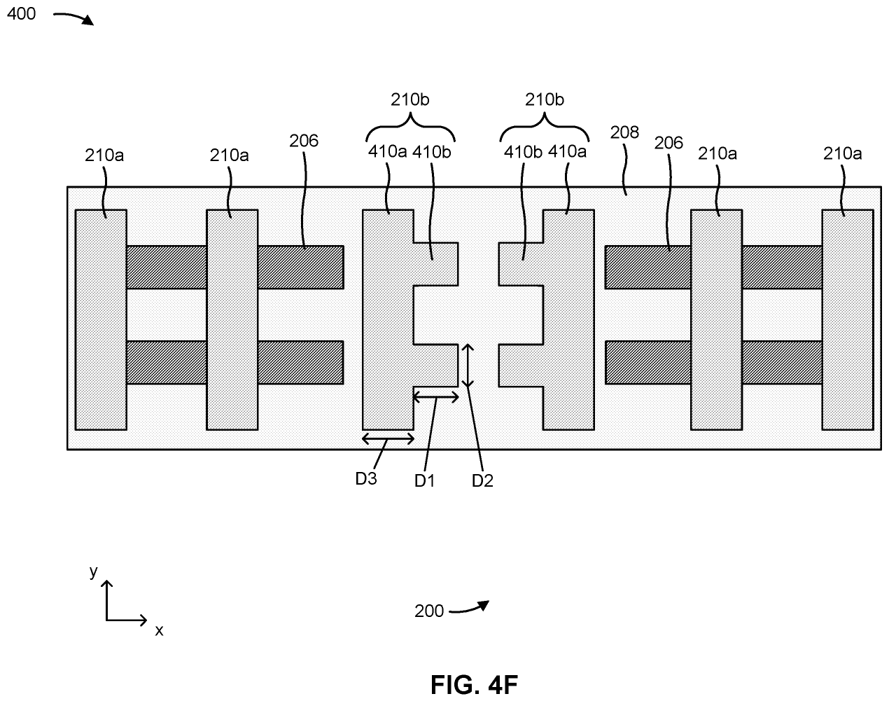

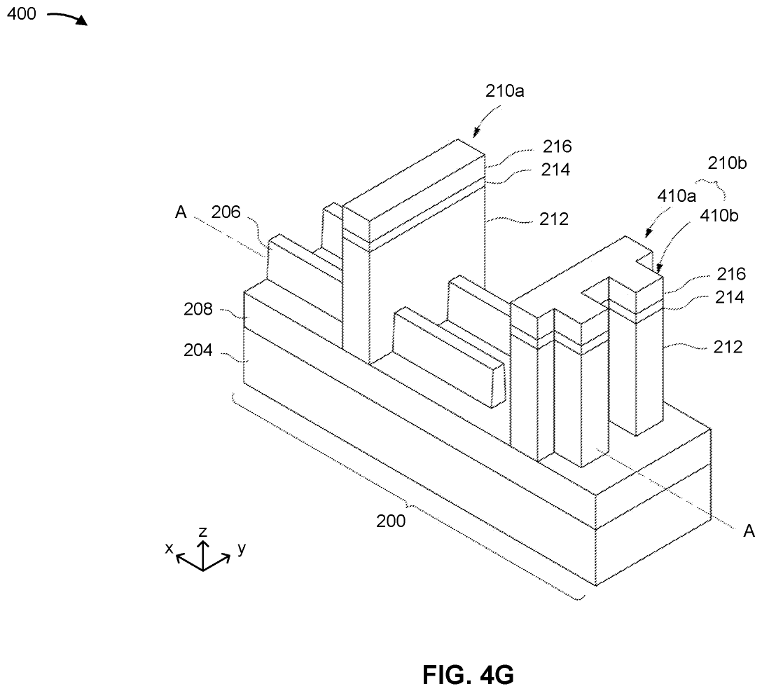

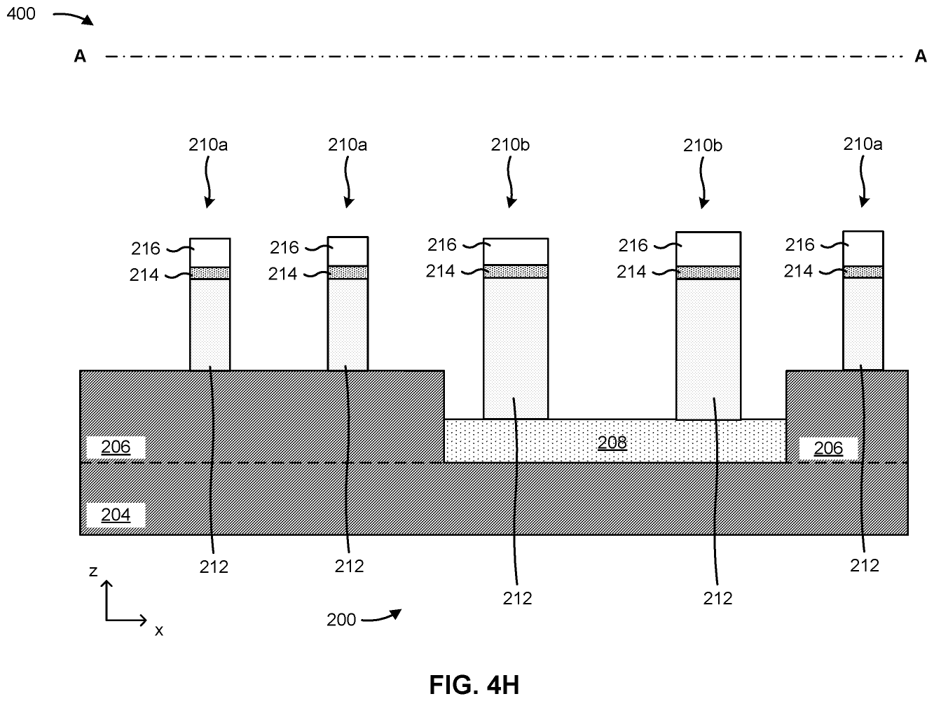

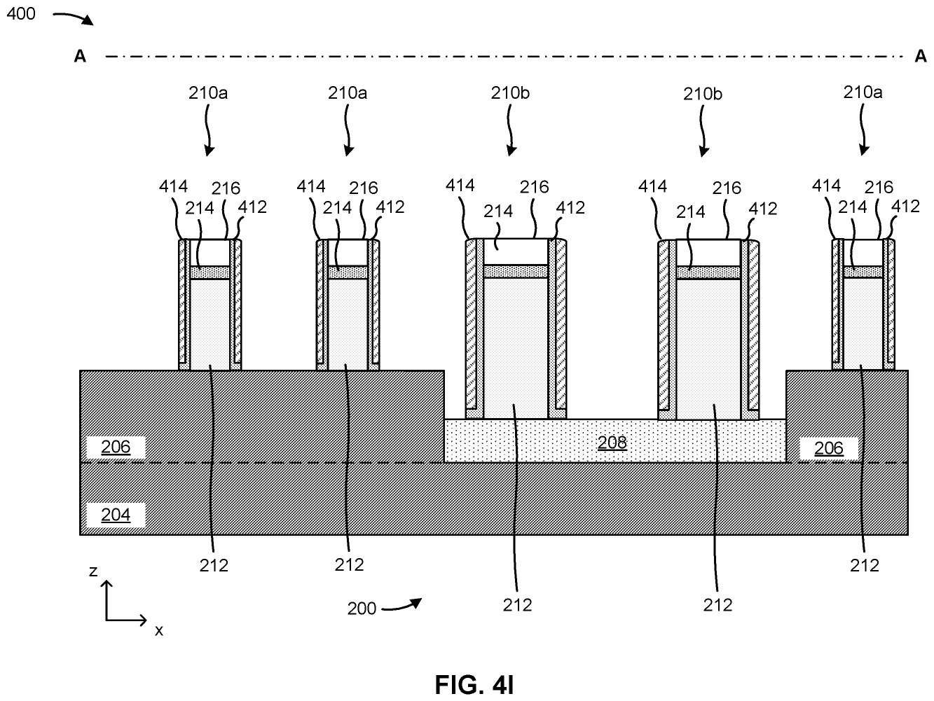

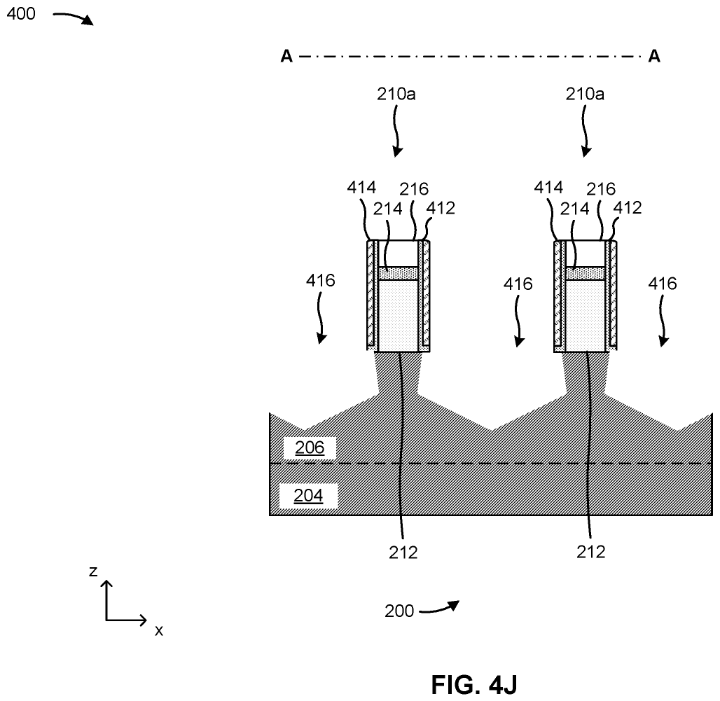

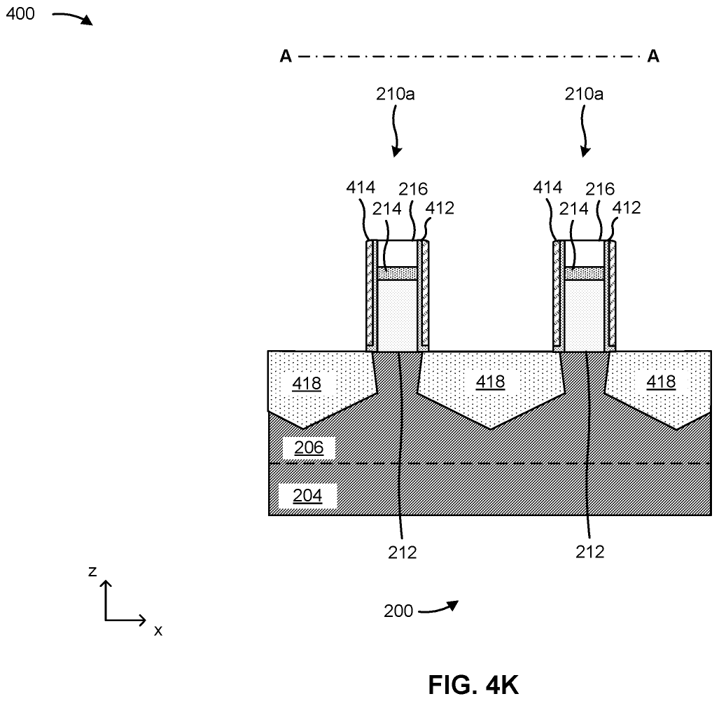

As indicated above, FIGS. 3A-3D are provided as an example. Other examples may differ from what is described with regard to FIGS. 3A-3D. FIGS. 4A-4K are diagrams of an example implementation 400 described herein. The example implementation 400 includes an example of forming source/drain regions in the source/drain areas 218 of the device region 202 of the semiconductor device 200. A subset of FIGS. 4A-4K is illustrated from the perspective of the cross-sectional plane A-A in FIG. 2 for the device region 202. In some implementations, the operations described in connection with the example implementation 400 are performed after the fin formation process described in connection with FIGS. 3A-3D.

FIG. 4A illustrates a cross-section view of a portion of the semiconductor device 200, along the cross-sectional plane A-A, that includes end portions of a plurality of fin structures 206. As shown in FIG. 4A, the STI region 208 may extend between ends of the plurality of fin structures 206 in the x direction. The plurality of fin structures 206 may extend from the substrate 204 and may extend above the STI region 208.

FIG. 4B illustrates a cross-section view of a portion of the semiconductor device 200, along the cross-sectional plane A-A. As shown in FIG. 4B, one or more layers may be formed over and/or on the plurality of fin structures 206, and/or over and/or on the STI region 208. For example, a polysilicon layer 402 may be formed over and/or on the plurality of fin structures 206, and/or over and/or on the STI region 208. As another example, a hard mask layer 404 may be formed over and/or on the polysilicon layer 402. As another example, a capping layer 406 may be formed over and/or on the hard mask layer 404.

The polysilicon layer 402 may include one or more layers of a polysilicon material. The deposition tool 102 may deposit the polysilicon layer 402 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the polysilicon layer 402 after the deposition tool 102 deposits the polysilicon layer 402.

The hard mask layer 404 may include any material suitable to pattern the polysilicon layer 402 with particular dimensions and/or attributes. Examples include silicon nitride, silicon oxynitride, silicon carbon nitride, or a combination thereof, among other examples. The deposition tool 102 may deposit the hard mask layer 404 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the hard mask layer 404 after the deposition tool 102 deposits the hard mask layer 404.

The capping layer 406 may include a dielectric oxide material, such as a silicon oxide (e.g., SiOₓ such as SiO₂), and/or another suitable dielectric material. The deposition tool 102 may deposit the capping layer 406 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the capping layer 406 after the deposition tool 102 deposits the capping layer 406.

As shown in FIGS. 4C and 4D, a pattern may be formed in a photoresist (PR) layer 408. The pattern in the photoresist layer 408 may be used to etch the polysilicon layer 402, the hard mask layer 404, and/or the capping layer 406 to form one or more dummy gate structures 210. As shown in FIG. 4C, the deposition tool 102 may form the photoresist layer 408 on the capping layer 406. The exposure tool 104 may expose the photoresist layer 408 to a radiation source to pattern the photoresist layer 408. The developer tool 106 may develop and remove portions of the photoresist layer 408 to expose the pattern, as shown in FIG. 4D.

FIG. 4E illustrates a top-down of the semiconductor device 200 in which top-down features of the pattern in the photoresist layer 408 are shown. As shown in FIG. 4E, remaining portions of the photoresist layer 408 may extend along the y direction in the semiconductor device 200. A first subset of the remaining portions of the photoresist layer 408 may extend across one or more fin structures 206, whereas a second subset of the remaining portions of the photoresist layer 408 may be located adjacent to ends of one or more fin structures 206 (e.g., the second subset of the remaining portions of the photoresist layer 408 are not located over a fin structure 206).

As shown in FIG. 4F-4H, the etch tool 108 may etch the polysilicon layer 402, the hard mask layer 404, and/or the capping layer 406 based on the pattern in the photoresist layer 408 to form dummy gate structures 210a and dummy gate structures 210b. In some implementations, the etch operation includes a plasma etch operation, a wet chemical etch operation, and/or another type of etch operation. In some implementations, a photoresist removal tool removes the remaining portions of the photoresist layer 408 (e.g., using a chemical stripper, plasma ashing, and/or another technique).

As shown in a top-down view of the semiconductor device 200 in FIG. 4F, the dummy gate structures 210a may be located over and/or on one or more fin structures 206. The fin structures 206 may extend in the x direction in the semiconductor device 200, whereas dummy gate structures 210a may extend in the y direction in the semiconductor device 200 (e.g., which is approximately perpendicular with the x direction). The dummy gate structures 210a may function as placeholder gate structures for metal gate structures that subsequently replace the dummy gate structures 210a, which enables a subset of semiconductor processing operations to be performed without causing damage to the metal gate structures.

The dummy gate structures 210b may be located on the STI region 208 adjacent to ends of one or more fin structures 206. In other words, the dummy gate structures 210b are not located over and/or on a fin structure 206. The dummy gate structures 210b may be referred to as edge poly gate structures in that the dummy gate structures 210b are located at the edges of one or more fin structures 206. The dummy gate structures 210b may be included to reduce the likelihood of and/or prevent damage to the dummy gate structures 210a. The dummy gate structures 210b may fill in spaces (e.g., unused space) between rows of fin structures 206. The spaces between the ends of the rows of the fin structures 206 might otherwise result in end loading during one or more semiconductor processing operations if the dummy gate structures 210b are not included. End loading refers to an increase in forces that are applied, during a semiconductor processing operation (e.g., a CMP operation, a wet cleaning operation), to dummy gate structures 210a that are located at or near the ends of the one or more fin structures 206 in the semiconductor device 200. The spaces between the ends of the rows of the fin structures 206, if not filled in with the dummy gate structures 210b, might enable processing materials and/or chemicals to build up and press against the dummy gate structures 210a that are located at or near the ends of the one or more fin structures 206. This may increase the likelihood that the dummy gate structures 210a that are located at or near the ends of the one or more fin structures 206 may delaminate and/or collapse.

As further shown in FIG. 4F, one or more of the dummy gate structures 210b may include a main body 410a and one or more support structures 410b. The main body 410a may extend in the y direction (e.g., the direction that is approximately perpendicular with the direction in which the fin structures 206 extend). The one or more support structures 410b may extend from the main body 410a in the x direction such that the one or more support structures 410b are approximately perpendicular with main body 410a.

The one or more support structures 410b may be included to reduce the likelihood of and/or prevent delamination, peeling, and/or collapse of the dummy gate structures 210b. As indicated above, the dummy gate structures 210b may be included to reduce the likelihood of and/or prevent damage to the dummy gate structures 210a during one or more semiconductor processing operations. During these semiconductor processing operations, the dummy gate structures 210b absorb forces that might otherwise be applied to the dummy gate structures 210a. As a result, the dummy gate structures 210b are also at risk of delamination, peeling, and/or collapse during the semiconductor processing operations. Accordingly, the one or more support structures 410b may be included to reinforce the dummy gate structures 210b, which increases the ability of the dummy gate structures 210b to absorb forces during the semiconductor processing operations, particularly forces in the x direction. A support structure 410b may have an approximately square-shaped configuration, a rounded configuration, an approximately rectangular-shaped configuration, an approximately triangular shaped configuration, and/or another configuration.

As further shown in FIG. 4F, a dummy gate structure 210b may include one or more dimensions. An example dimension D1 may correspond to a length of a support structure 410b in the x direction. Another example dimension D2 may correspond to a width of a support structure 410b in the y direction. Another example dimension D3 may correspond to a length of a main body 410a in the x direction. In some implementations, the length of a support structure 410b in the x direction (e.g., the dimension D1) may be included in a range of approximately 1.5 times to approximately 2.5 times the length of the main body 410a in the x direction (e.g., the dimension D3) to provide sufficient structural support for the dummy gate structure 210b, and to achieve a sufficiently low likelihood of peeling, delamination, and/or collapse during semiconductor processing of the semiconductor device 200. For example, if the length of the main body 410a in the x direction (e.g., the dimension D3) is approximately 20 nanometers, the length of a support structure 410b in the x direction (e.g., the dimension D1) may be included in a range of approximately 30 nanometers to approximately 50 nanometers. However, other values for the range are within the scope of the present disclosure. In some implementations, the width of a support structure 410b in the y direction (e.g., the dimension D2) may be included in a range of approximately 1.5 times to approximately 2.5 times the length of the main body 410a in the x direction (e.g., the dimension D3) to provide sufficient structural support for the dummy gate structure 210b, and to achieve a sufficiently low likelihood of peeling, delamination, and/or collapse during semiconductor processing of the semiconductor device 200. For example, if the length of the main body 410a in the x direction (e.g., the dimension D3) is approximately 10 nanometers, the width of a support structure 410b in the y direction (e.g., the dimension D2) may be included in a range of approximately 15 nanometers to approximately 25 nanometers. However, other values for the range are within the scope of the present disclosure.

FIG. 4G illustrates a perspective view of a portion of the semiconductor device 200 after formation of the dummy gate structures 210a and 210b. As shown in FIG. 4G, the dummy gate structures 210a and 210b may each include a gate electrode layer 212, a hard mask layer 214, and/or a capping layer 216. In some implementations, the dummy gate structures 210a and/or 210b may include a different combination of layers. The dummy gate structures 210a are formed and included over the fin structures 206, and around the sides of the fin structures 206 such that the dummy gate structures 210 surround the fin structures 206 on at least three sides of the fin structures 206. The dummy gate structures 210b are formed and included adjacent to ends of one or more fin structures 206, and are not included on and around sides of a fin structure 206.

As further shown in FIG. 4G, the bottom surface of the dummy gate structures 210b are located on the top surface of the STI region 208. The bottom surface of a dummy gate structure 210b may be substantially flat across the bottom surface, whereas the bottom surface of a dummy gate structure 210a may have portions that are located at different heights in the semiconductor device 200 because the dummy gate structure 210a wraps around one or more fin structures 206. For example, a first portion of a bottom surface of a dummy gate structure 210a may be located on the STI region 208 at a first height, and a second portion of the bottom surface of the dummy gate structure 210a may be located on a fin structure 206 at a second height that is greater relative to the first height. A bottom surface of a dummy gate structure 210b (for both the main body 410a and the one or more support structure 410b of the dummy gate structure 210b) may be located a height in the semiconductor device 200 that is lesser/lower relative to the second height of the second portion of the bottom surface of the dummy gate structure 210a that is located on a fin structure 206. A support structure 410b may be approximately a same height as a main body 410a of a dummy gate structure 210b.

FIG. 4H illustrates a cross-section view of a portion of the semiconductor device 200, along the cross-sectional plane A-A. As shown in FIG. 4H, the dummy gate structures 210a are formed and included over and/or on the fin structures 206. The dummy gate structures 210b are formed and included over and/or on the STI region 208 adjacent to ends of the fin structures 206. A cross-sectional width of a dummy gate structure 210b along the cross-sectional plane A-A in the x direction may be greater relative to a cross-sectional width of a dummy gate structure 210a along the cross-sectional plane A-A in the x direction because of the inclusion of the one or more support structures 410b that extend in the x direction.

In some implementations, a height of a top surface of a dummy gate structure 210a (e.g., which may correspond to a top surface of a capping layer 216 included in the dummy gate structure 210a) in the semiconductor device 200, and a height of a top surface of a dummy gate structure 210b (e.g., which may correspond to a top surface of a capping layer 216 included in the dummy gate structure 210b) in the semiconductor device 200, may be approximately the same height. In some implementations, a height of a top surface of a dummy gate structure 210a (e.g., which may correspond to a top surface of a capping layer 216 included in the dummy gate structure 210a) in the semiconductor device 200 may be greater relative to a height of a top surface of a dummy gate structure 210b (e.g., which may correspond to a top surface of a capping layer 216 included in the dummy gate structure 210b) in the semiconductor device 200.

In some implementations, a wet cleaning operation may be performed after etching the layers 402-406 to form the dummy gate structure 210a and 210b. The wet cleaning operation may include removing residual materials, contaminants, and/or native oxides from the semiconductor device 200 using one or more types of wet chemicals. The dummy gate structures 210b may protect the dummy gate structures 210a during the wet cleaning operation, thereby reducing end loading on the dummy gate structures 210a. Moreover, the one or more support structures 410b may support the dummy gate structures 210b during the wet cleaning operation, which reduces the likelihood of peeling, delamination, and/or collapse of the dummy gate structures 210b.

As shown in FIG. 4I, seal spacer layers 412 may be formed on sidewalls of the dummy gate structures 210a and 210b. The seal spacer layers 412 may be conformally deposited (e.g., by the deposition tool 102) and may include a silicon oxycarbide (SiOC), a nitrogen free SiOC, or another suitable material. In some implementations, the seal spacer layers 412 may be formed by an ALD operation in which various types of precursor gasses including silicon (Si) and carbon (C) are sequentially supplied in a plurality of alternating cycles to form the seal spacer layers 412, among other example deposition techniques.

As further shown in FIG. 4I, bulk spacer layers 414 may be formed on the seal spacer layers 412. The bulk spacer layers 414 may be formed of similar materials as the seal spacer layers 412. However, the bulk spacer layers 414 may formed without plasma surface treatment that is used for the seal spacer layers 412. Moreover, the bulk spacer layers 414 may be formed to a greater thickness relative to the thickness of the seal spacer layers 412.

In some implementations, the seal spacer layers 412 and the bulk spacer layers 414 are conformally deposited (e.g., by the deposition tool 102) on the dummy gate structures 210a and 210b, and on the fin structures 206. The seal spacer layers 412 and the bulk spacer layers 414 are then patterned (e.g., by the deposition tool 102, the exposure tool 104, and the developer tool 106) and etched (e.g., by the etch tool 108) to remove the seal spacer layers 412 and the bulk spacer layers 414 from the tops of the dummy gate structures 210a and 210b, and from the fin structures 206.

FIG. 4J illustrates a cross-section view of a portion of the semiconductor device 200, along the cross-sectional plane A-A, that includes a fin structure 206. As shown in FIG. 4J, recesses 416 are formed in the fin structure 206 between dummy gate structures 210a in an etch operation. The etch operation may be referred to a first strained source/drain (SSD) etch operation, and the recesses 416 may be referred to as strained source/drain recesses. In some implementations, the etch tool 108 may perform the first etch operation, which may include a plasma etch technique, a wet chemical etch technique, and/or another type of etch technique.

In some implementations, a plurality of etch operations are performed to form recesses 416 for different types of transistors. For example, a photoresist layer may be formed over and/or on a first subset of the fin structures 206 and over and/or on a first subset of the dummy gate structures 210a such that a second subset of the fin structures 206 between a second subset of the dummy gate structures 210a such that p-type source/drain regions and n-type source/drain regions may be formed in separate epitaxial operations.

As shown in FIG. 4K, source/drain regions 418 are formed in the recesses 416 of the semiconductor device 200 over the substrate 204. The deposition tool 102 forms the source/drain regions 418 by an epitaxial operation, in which layers of the epitaxial material are deposited in the recesses 416 such that the layers of p-type source/drain regions and/or layers of n-type source/drain regions are formed by epitaxial growth in a particular crystalline orientation. The source/drain regions 418 are included between the dummy gate structures 210a and at least partially below and/or lower than the dummy gate structures 210a. Moreover, the source/drain regions 418 at least partially extend above the top surface of the fin structures 206.

The material (e.g., silicon (Si), gallium (Ga), or another type of semiconductor material) that is used to form the source/drain regions 418 may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. The resulting material of p-type source/drain regions include silicon germanium (SiₓGe₁₋ⱼ, where j can be in a range from approximately 0 to approximately 100) or another type of p-doped semiconductor material. Examples of n-type dopants that may be used in the epitaxial operation include phosphorous (P) or arsenic (As), among other examples. The resulting material of n-type source/drain regions include silicon phosphide (SiₓP_{y}) or another type of n-doped semiconductor material.

As indicated above, FIGS. 4A-4K are provided as an example. Other examples may differ from what is described with regard to FIGS. 4A-4K.

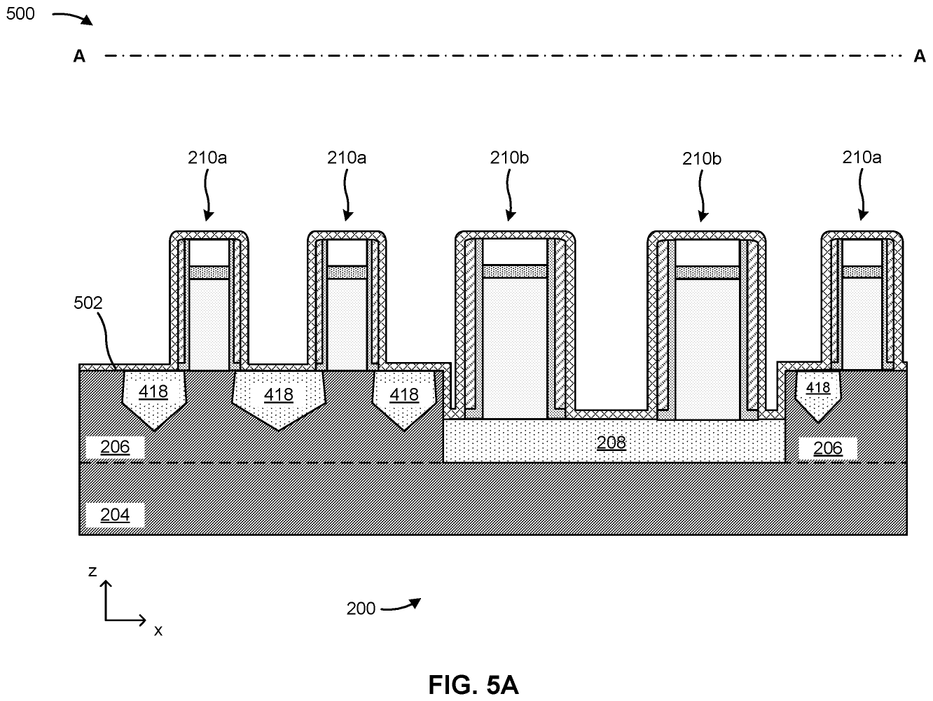

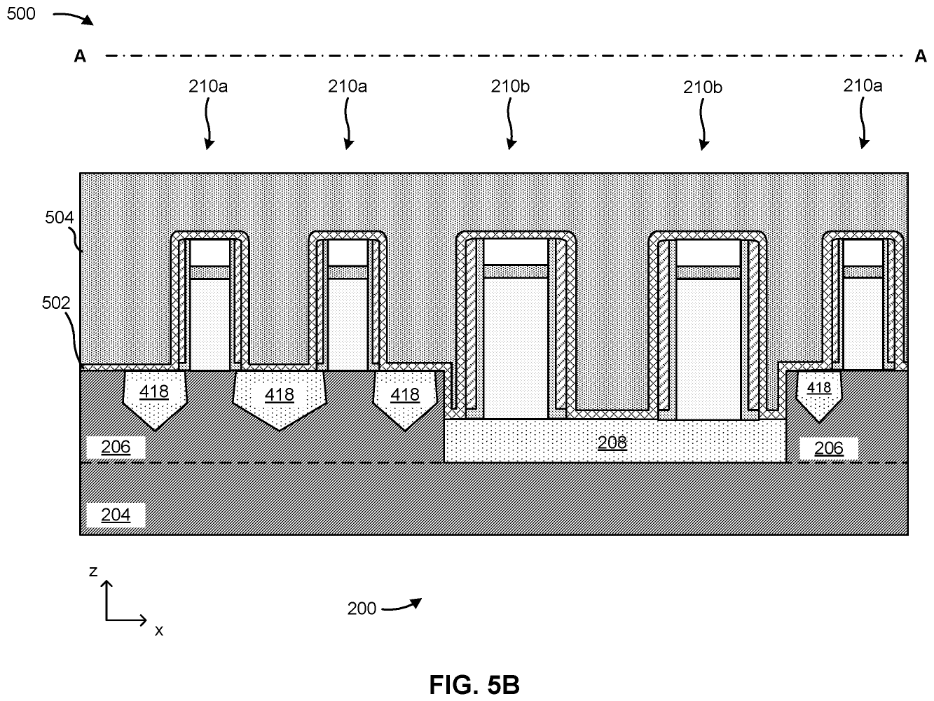

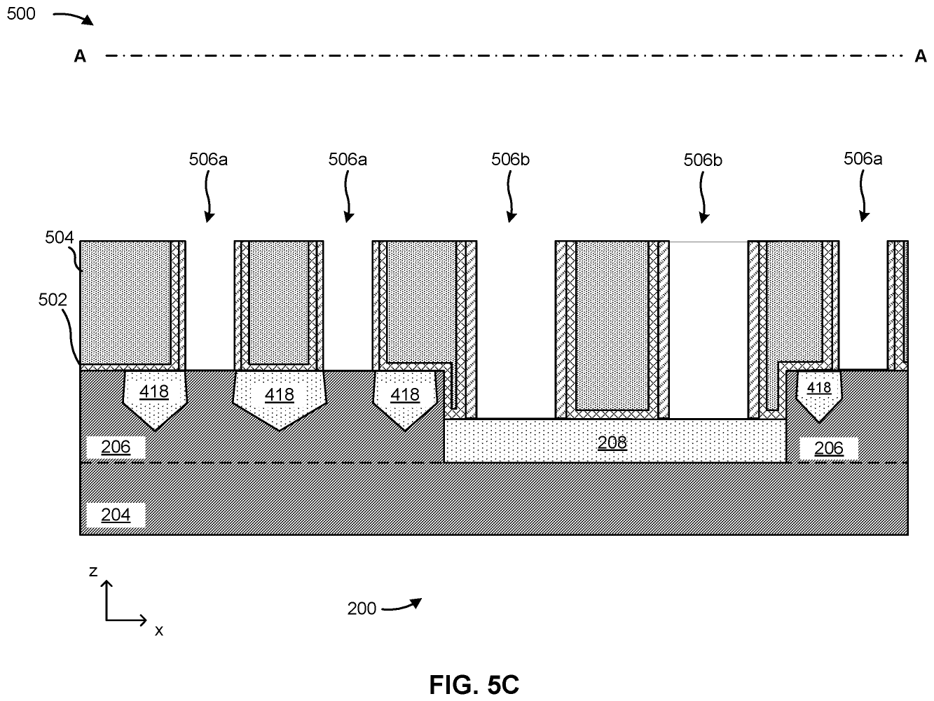

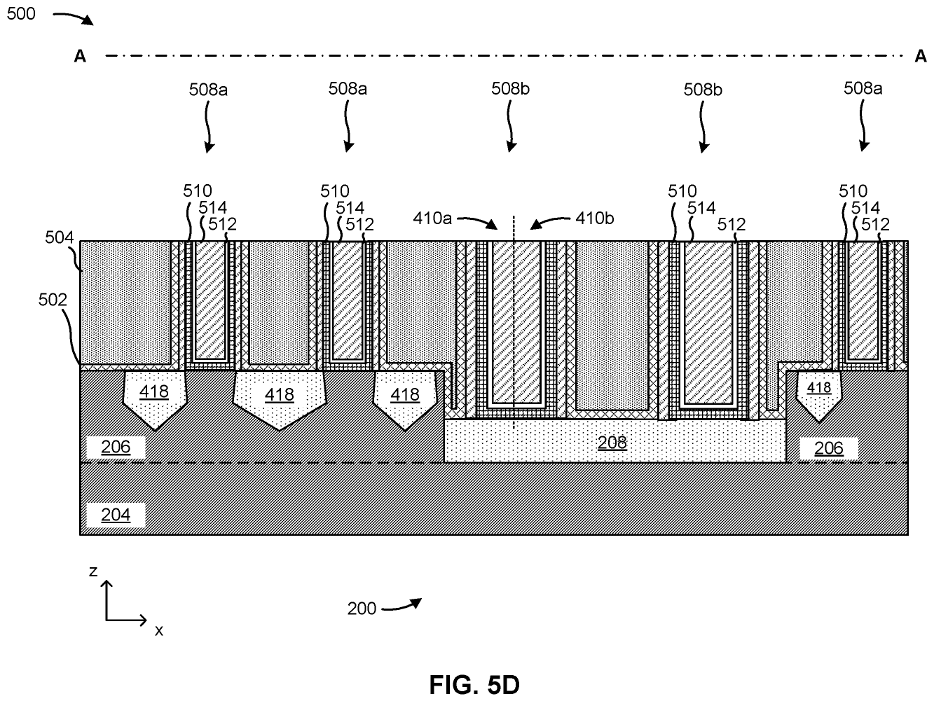

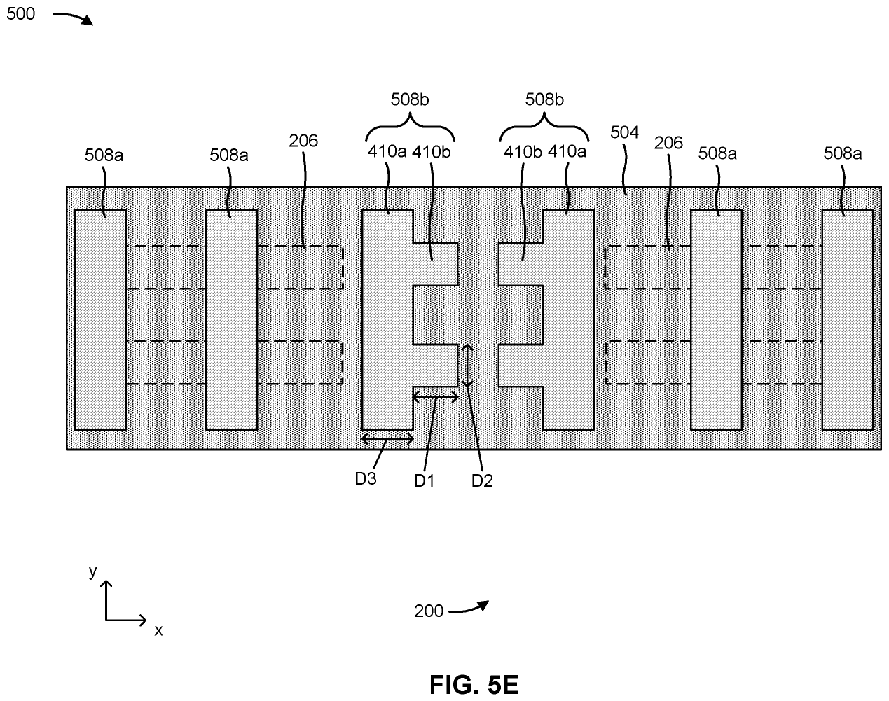

FIGS. 5A-5E are diagrams of an example implementation 500 described herein. The example implementation 500 includes an example dummy gate replacement process, in which the dummy gate structures 210a and 210b are replaced with high-k gate structures and/or metal gate structures. FIGS. 5A-5E are illustrated from the perspective of the cross-sectional plane A-A in FIG. 2 for the device region 202.

As shown in FIG. 5A, a contact etch stop layer (CESL) 502 is conformally deposited (e.g., by the deposition tool 102) over the source/drain regions 418, over the dummy gate structures 210a and 210b, over the exposed portions of the STI region 208, and on the sidewalls of the bulk spacer layers 414. The CESL 502 may provide a mechanism to stop an etch process when forming contacts or vias for the semiconductor device 200. The CESL 502 may be formed of a dielectric material having a different etch selectivity from adjacent layers or components. The CESL 502 may include or may be a nitrogen containing material, a silicon containing material, and/or a carbon containing material. Furthermore, the CESL 502 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The deposition tool 102 may deposit the CESL 502 using a conformal deposition process, such as ALD, CVD, or another deposition technique.

As shown in FIG. 5B, an interlayer dielectric (ILD) layer 504 is formed (e.g., by the deposition tool 102) over and/or on the CESL 502. The ILD layer 504 fills in the areas between the dummy gate structures 210a and 210b, over the source/drain regions 418, and/or over the exposed portions of the STI region 208. The ILD layer 504 is formed to permit a replacement gate structure process to be performed in the semiconductor device 200, in which metal gate structures are formed to replace the dummy gate structures 210a and 210b. The ILD layer 504 may be referred to as an ILD zero (ILDO) layer.

In some implementations, the ILD layer 504 is formed to a height (or thickness) such that the ILD layer 504 covers the dummy gate structures 210a and/or 210b. In these implementations, a subsequent CMP operation (e.g., performed by the planarization tool 110 is performed to planarize the ILD layer 504 such that the top surfaces of the ILD layer 504 are approximately at a same height as the top surfaces of the dummy gate structures 210a and/or 210b. The CMP operation increases the uniformity of the ILD layer 504.

As shown in FIG. 5C, the replacement gate operation is performed (e.g., by one or more of the semiconductor processing tools 102-112) to remove the dummy gate structures 210a and 210b from the semiconductor device 200. The removal of the dummy gate structures 210a leaves behind openings (or recesses) 506a between the bulk spacer layers 414 and between the source/drain regions 418. The removal of the dummy gate structures 210b leaves behind openings (or recesses) 506b between the bulk spacer layers 414 over the STI region 208. The dummy gate structures 210a and 210b may be removed in one or more etch operations includes a plasma etch technique, which may include a wet chemical etch technique, and/or another type of etch technique.

As shown in FIG. 5D, the replacement gate operation continues where deposition tool 102 and/or the plating tool 112 forms replacement gate structures in the recesses 506a and 506b. For example, active gate structures 508a may be formed in the recesses 506a between the bulk spacer layers 414 and between the source/drain regions 418. The active gate structures 508a may be “active” in that the active gate structures 508a may be gate structures that perform electrical functions for transistors in the semiconductor device 200. The active gate structures 508a may be included over and/or on one or more fin structures 206, and may wrap around at least three sides of the one or more fin structures 206. As another example, non-active gate structures 508b may be formed in the recesses 506b between the bulk spacer layers 414 and over the STI region 208. The non-active gate structures 508b may be “non-active” in that the non-active gate structures 508b may be gate structures that do not perform electrical functions for transistors in the semiconductor device 200. The non-active gate structures 508b may be included as a remnant of the use of the dummy gate structures 210b. The non-active gate structures 508b may be located adjacent to ends of one or more fin structures 206.

The gate structures 508a and 508b may include metal gate structures, high-k gate structures, or other types of gate structures. The gate structures 508a and 508b may include an interfacial layer (not shown), a high-k dielectric layer 510, a work function tuning layer 512, and a metal electrode structure 514 formed therein to form the gate structures 508a and 508b. In some implementations, the gate structures 508a and/or 508b may include other compositions of materials and/or layers.

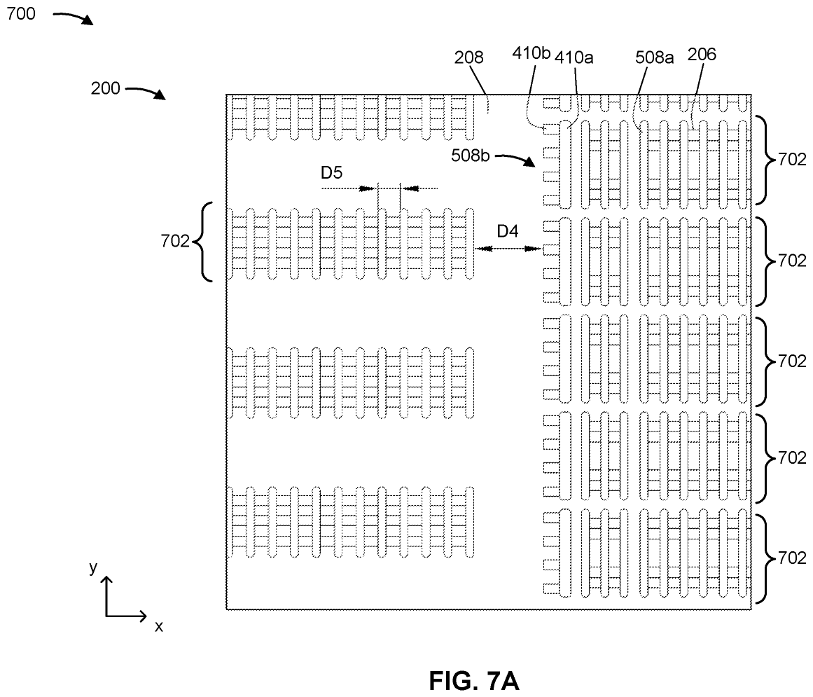

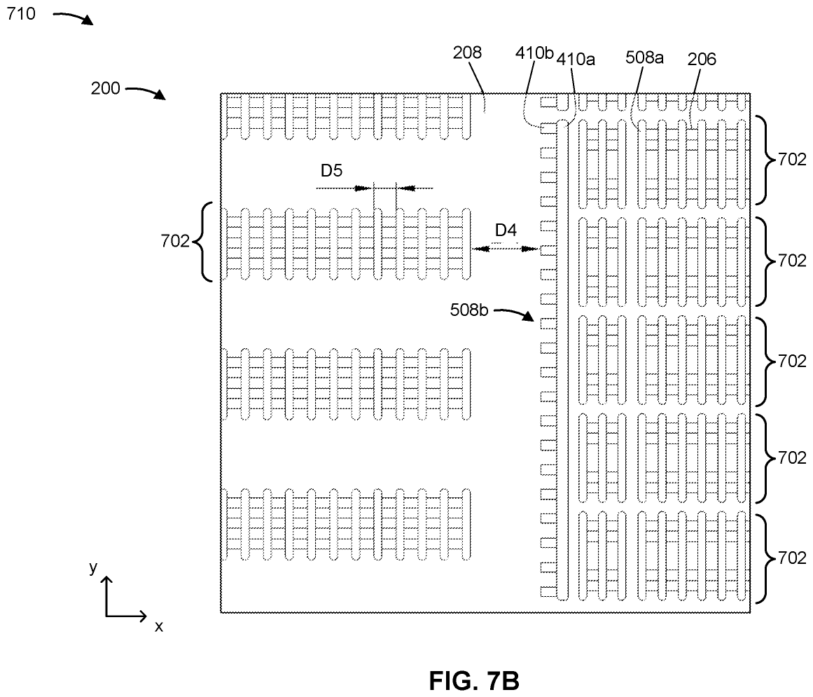

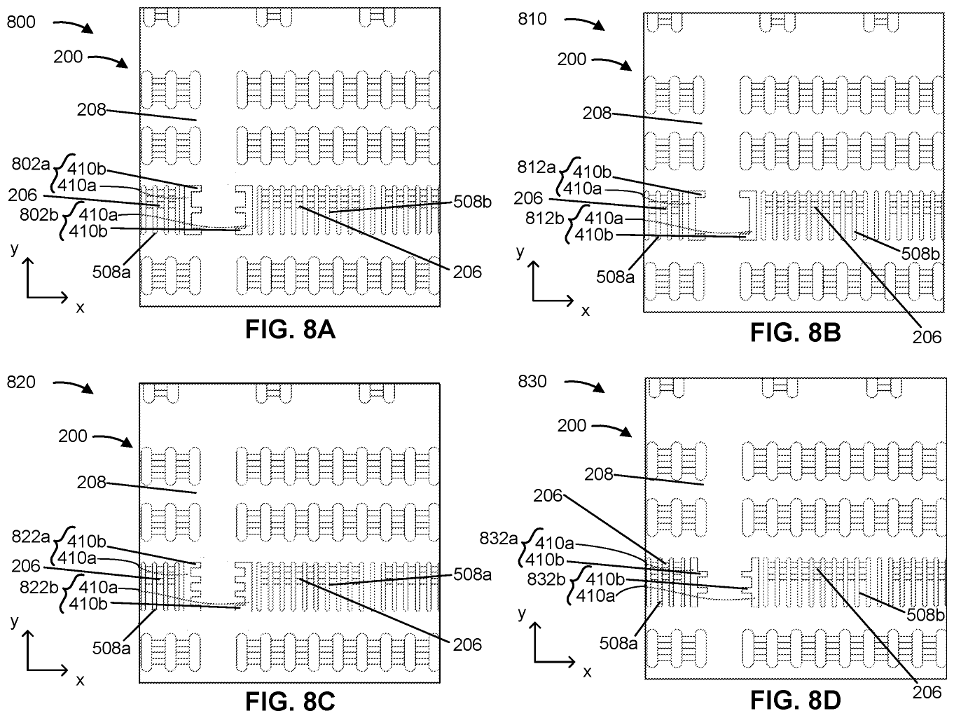

FIG. 5E illustrates a top-down view of the semiconductor device 200 after formation of the active gate structures 508a and non-active gate structures 508b. As shown in FIG. 5E, the non-active gate structures 508b may include a main body 410a and one or more support structures 410b. In some implementations, one or more of the non-active gate structures 508b, the main body 410a of the non-active gate structures 508b, and/or the one or more support structures 410b of the non-active gate structures 508b may include one or more configurations, features, properties, and/or dimensions (e.g., dimensions D1-D3) of the dummy gate structures 210b described above in connection with FIGS. 4F-4H. In some implementations, one or more of the non-active gate structures 508b may be arranged, in the semiconductor device 200, in one or more of the configurations described in connection with FIGS. 7A, 7B, 8A-8D, and/or 9A-9D.

In this way, in some implementations, the semiconductor device 200 may include one or more fin structures 206 extending above a substrate 204, where the one or more fin structures 206 extend in a first direction (e.g., the x direction) in a top-down view of the semiconductor device 200; an active gate structure 508a that wraps around the one or more fin structures 206 on at least three sides of the one or more fin structures 206, where the active gate structure 508a extends in a second direction (e.g., the y direction), in the top-down view of the semiconductor device 200, that is approximately perpendicular with the first direction; and a non-active gate structure 508b on an STI region 208, where the non-active gate structure 508b is adjacent to ends of the one or more fin structures 206 and includes a main body 410a that extends in the second direction and one or more support structures 410b that extend from the main body 410a in the first direction.

As indicated above, FIGS. 5A-5E are provided as an example. Other examples may differ from what is described with regard to FIGS. 5A-5E.

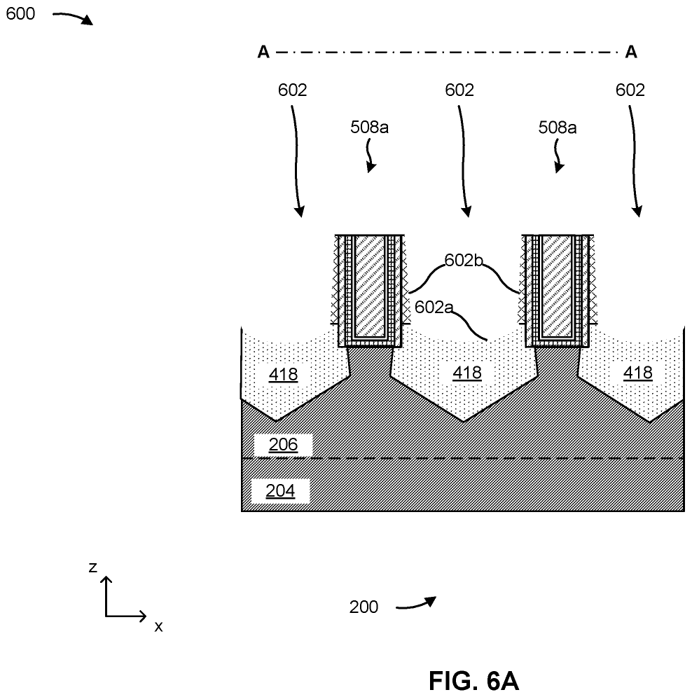

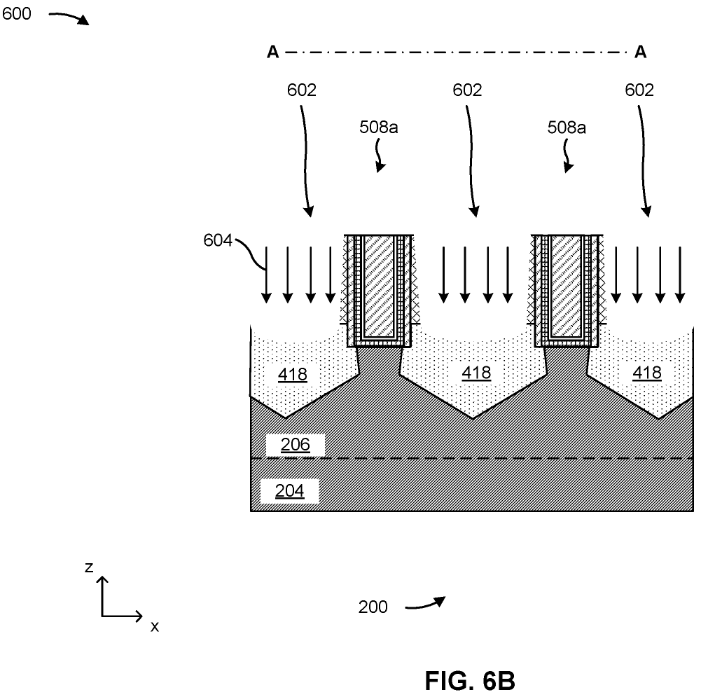

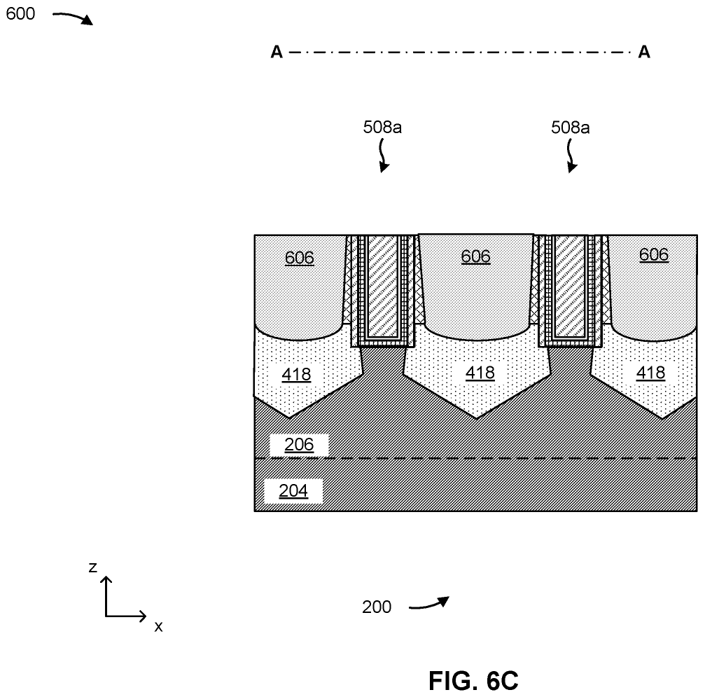

FIGS. 6A-6C are diagrams of an example implementation 600 described herein. The example implementation 600 includes an example of forming conductive structures (e.g., metal gate contacts or MDs) in the device region 202 of the semiconductor device 200. FIGS. 6A-6C are illustrated from the perspective of the cross-sectional plane A-A in FIG. 2 for the device region 202.

As shown in FIG. 6A, openings (or recesses) 602 are formed through one or more dielectric layers and to the source/drain regions 418. In particular, the CESL 502 and the ILD layer 504 between the active gate structures 508a in the device region 202 are etched to form the openings 602 between the active gate structures 508a and to the source/drain regions 418. In some implementations, the openings 602 are formed in a portion of the source/drain regions 418 such that recesses extend into a portion of the source/drain regions 418. An opening 602 includes a bottom surface 602a corresponding to a top surface of an associated source/drain region 418, and a plurality of sidewalls 602b corresponding to sides of the CESL 502 and/or the ILD layer 504.

In some implementations, a pattern in a photoresist layer is used to form the openings 602. In these implementations, the deposition tool 102 forms the photoresist layer on the ILD layer 504, and on the active gate structures 508a. The exposure tool 104 exposes the photoresist layer to a radiation source to pattern the photoresist layer. The developer tool 106 develops and removes portions of the photoresist layer to expose the pattern. The etch tool 108 etches into the ILD layer 504 to form the openings 602. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the openings 602 based on a pattern.

As shown in FIG. 6B, a pre-clean operation is performed to clean the surfaces in the recesses 602. In particular, the semiconductor device 200 may be positioned in a first processing chamber of the deposition tool 102 (e.g., a pre-clean processing chamber), the first processing chamber may be pumped down to an at least partial vacuum (e.g., pressurized to a pressure that is included in a range of approximately 5 Torr to approximately 10 Torr, or to another pressure), and the bottom surfaces 602a and the sidewalls 602b in the openings 602 are cleaned using a plasma-based and/or a chemical-based pre-clean agent 604. The pre-clean operation is performed to clean (e.g., remove) oxides and other contaminants or byproducts from the top surfaces source/drain regions 418 that may have formed after the formation of the openings 602.

As shown in FIG. 6C, conductive structures 606 are formed in the device region 202. In particular, conductive structures 606 are formed in the openings 602 between the active gate structures 508a and over the source/drain regions 418 in the openings 602. The deposition tool 102 and/or the plating tool 112 deposits the conductive structures 606 by a CVD technique, a PVD technique, an ALD technique, an electroplating technique, another deposition technique described above in connection with FIG. 1, and/or a deposition technique other than as described above in connection with FIG. 1. In some implementations, one or more additional layers are formed in the openings 602 prior to formation of the conductive structures 606. As an example, a metal silicide layer (e.g., titanium silicide (TiSiₓ) or another metal silicide layer) may be formed on the top surfaces of the source/drain regions 418 prior to formation of the conductive structures 606. As another example, one or more barrier layers may be formed on the bottom surfaces 602a and/or on the sidewalls 602b in the openings 602 prior to formation of the conductive structures 606. As another example, one or more adhesion layers may be formed on the bottom surfaces 602a and/or on the sidewalls 602b in the openings 602 prior to formation of the conductive structures 606.

As indicated above, FIGS. 6A-6C are provided as an example. Other examples may differ from what is described with regard to FIGS. 6A-6C.

FIGS. 7A and 7B are diagrams of example implementations of the semiconductor device 200 described herein. FIGS. 7A and 7B illustrate top-down views of the semiconductor device 200, in which example implementations of non-active gate structure configurations are illustrated. As described herein, the non-active gate structures may include one or more support structures that extend from a main body of the non-active gate structures.

FIG. 7A illustrates an example implementation 700 of the semiconductor device 200 described herein. As shown in FIG. 7A, the semiconductor device 200 may include a plurality of rows of fin structures 206 that extend in the x direction in the semiconductor device 200. The semiconductor device 200 may further include a plurality of active gate structures 508a that wrap around at least three sides of one or more of the fin structures 206. The active gate structures 508a may extend in the y direction in the semiconductor device 200, which may be approximately perpendicular with the x direction. As shown in FIG. 7A, the semiconductor device 200 may include a plurality of non-active gate structures 508b that are located adjacent to ends of one or more of the fin structures 206.

As further shown in FIG. 7A, subsets of the fin structures 206 may be arranged in fin groups 702. A fin group 702 may include a plurality of fin structures 206 across which a subset of active gate structure 508a may span. In other words, a subset of active gate structure 508a may extend or span across the fin structures 206 in a fin group 702. Fin groups 702 may be located adjacent to one another in the x direction and/or in the y direction in the semiconductor device 200.

As further shown in FIG. 7A, the semiconductor device 200 may include a plurality of non-active gate structures 508b. Each non-active gate structure 508b may be associated with, and may extend alongside a respective fin group 702. In other words, in the example implementation 700, a non-active gate structure 508b is contained within a fin group 702 and does not extend alongside more than one fin group 702.

As an example, a first plurality of fin structures 206 may be included in a first fin group 702, where at least one first active gate structure 508a extends across the first fin group 702, and where a first non-active gate structure 508b extends alongside the first active gate structure 508a and along ends of the fin structures 206 included in the fin group 702. A second plurality of fin structures 206, included in a second fin group 702 that is adjacent to the first fin group 702, may extend in approximately a same direction as the fin structures 206 in the first fin group 702. A second active gate structure 508a may extend across the second fin group 702 and may wrap around at least three sides of the fin structures 206 in the second fin group 702. A second non-active gate structure 508b adjacent to ends of the fin structures in the second fin group 702 may extend alongside the second active gate structure 508a and alongside the ends of the fin structure 206 in the second fin group 702.

The first and second non-active gate structure 508b may each be located on the STI region 208 of the semiconductor device 200 and may include a main body 410a that extends in the y direction, and one or more support structures 410b that extend from the main body 410a in the x direction.

As further shown in FIG. 7A, a non-active gate structure 508b may be included in an area of the semiconductor device 200 in which a distance threshold can be achieved between the non-active gate structure 508b and another active structure in the semiconductor device 200 (e.g., another active structure that is not included in the fin group 702 that is associated with the non-active gate structure 508b). Here, the distance between the non-active gate structure 508b and another active structure in the semiconductor device 200 (illustrated as dimension D4) satisfies the distance threshold. In some implementations, the distance threshold (e.g., which may correspond to a threshold amount of spacing) may be based on an active gate structure pitch (illustrated as dimension D5) of active gate structures 508a in the semiconductor device 200. The active gate structure pitch may refer to the distance between the same edges of adjacent active gate structures 508a (e.g., the left side edges of adjacent active gate structures 508a, the right side edges of adjacent active gate structures 508a). In some implementations, the distance threshold is at least two times the size of the active gate structure pitch (e.g., dimension D5) of the semiconductor device 200 to provide sufficient spacing from active structures in the semiconductor device 200. However, other values for the distance threshold are within the scope of the present disclosure.

FIG. 7B illustrates an example implementation 710 of the semiconductor device 200 described herein. As shown in FIG. 7B, the example implementation 710 of the semiconductor device 200 may include a similar combination of structures and/or dimensions as the example implementation 700 of the semiconductor device 200 illustrated in FIG. 7A. However, the example implementation 710 of the semiconductor device 200 illustrated in FIG. 7B includes at least one non-active gate structure 508b that continuously extends alongside a plurality of fin groups 702.

As an example, the semiconductor device 200 may include a first plurality of fin structures 206 that are included in a first fin group 702, and a first active gate structure 508a that extends across the first fin group 702. The semiconductor device 200 may further include a second plurality of fin structures 206, included in a second fin group 702 adjacent to the first fin group 702, that extends in the x direction, and a second active gate structure 508a that extends across the second fin group 702 in the y direction. The semiconductor device 200 may further include a non-active gate structure 508b that continuously extends alongside the first active gate structure 508a and the second active gate structure 508a and spans the first fin group 702 and the second fin group 702, as illustrated in the example in FIG. 7B.

As indicated above, FIGS. 7A and 7B are provided as an example. Other examples may differ from what is described with regard to FIGS. 7A and 7B. In some implementations, the semiconductor device 200 may include a combination of a non-active gate structure 508b that extends alongside a single fin group (e.g., as illustrated in the example implementation 700 in FIG. 7A), and a non-active gate structure 508b that continuously extends alongside a plurality of fin groups (e.g., as illustrated in the example implementation 710 in FIG. 7B).

FIGS. 8A-8D are diagrams of example implementations of the semiconductor device 200 described herein. FIGS. 8A-8D illustrate top-down views of the semiconductor device 200, in which example implementations of non-active gate structure configurations are illustrated. As described herein, the non-active gate structures may include one or more support structures that extend from a main body of the non-active gate structures. The example implementations of the semiconductor device 200 illustrated in FIGS. 8A-8D include various configurations of non-active gate structures in which adjacent non-active gate structures have a same quantity of support structures and/or have symmetrical arrangements of support structures.

FIG. 8A illustrates an example implementation 800 of the semiconductor device 200. The semiconductor device 200 may include one or more first fin structures 206 extending above a substrate, where the one or more first fin structures 206 extend in a first direction (e.g., an x direction) in the top-down view of the semiconductor device 200. The semiconductor device 200 may include one or more first active gate structure 508a that wrap around the one or more first fin structures 206 on at least three sides of the one or more first fin structures 206, where the one or more first active gate structures 508a extend in a second direction (e.g., the y direction), in the top-down view of the semiconductor device 200, that is approximately perpendicular with the first direction (e.g., the x direction).

As shown in FIG. 8A, the semiconductor device 200 may include a first non-active gate structure 802a (e.g., a non-active gate structure 508b) on an STI region 208, where the first non-active gate structure 802a is adjacent to ends of the one or more first fin structures 206. The first non-active gate structure 802a may include a first main body 410a that extends in the second direction (e.g., in the y direction) and one or more first support structures 410b that extend from the first main body 410a in the first direction (e.g., the x direction).

The semiconductor device 200 may include one or more second fin structures 206 extending above a substrate, where the one or more second fin structures 206 extend in the first direction (e.g., the x direction). The semiconductor device 200 may include one or more second active gate structures 508a that wrap around the one or more second fin structures 206 on at least three sides of the one or more second fin structures 206, where the one or more second active gate structures 508a extend in the second direction (e.g., in the y direction).

As shown in FIG. 8A, the semiconductor device 200 may include a second non-active gate structure 802b (e.g., a non-active gate structure 508b) on the STI region 208 and adjacent to the first non-active gate structure 802a. The second non-active gate structure 802b is adjacent to ends of the one or more second fin structures 206. The second non-active gate structure 802b may include a second main body 410a that extends in the second direction (e.g., the y direction) and one or more second support structures 410b that extend from the second main body 410a in the first direction (e.g., the x direction).

As further shown in FIG. 8A, the one or more first support structures 410b may extend from a side of the first main body 410a that is different from a side of the second main body 410a from which the one or more support structures 410b extend. In this way, the one or more first support structures 410b of the first non-active gate structure 802a and the one or more second support structures 410b of the second non-active gate structure 802b are facing each other. Thus, the one or more first fin structures 206 may be located on a first side of the first main body 410a of the first non-active gate structure 802a, and the one or more first support structures 410b may be located on a second side of the first main body 410a of the first non-active gate structure 802a, where the first side and the second side are opposing sides. In other words, the one or more first support structures 410b of the first non-active gate structure 802a may be facing away from the one or more first fin structures 206 and toward the second non-active gate structure 802b.

The one or more second fin structures 206 may be located on a first side of the second main body 410a of the second non-active gate structure 802b, and the one or more second support structures 410b may be located on a second side of the second main body 410a of the second non-active gate structure 802b, where the first side and the second side are opposing sides. In other words, the one or more second support structures 410b of the second non-active gate structure 802b may be facing away from the one or more second fin structures 206 and toward the first non-active gate structure 802a.

Alternatively, the one or more first support structures 410b and/or the one or more second support structures 410b may be arranged in a different configuration. For example, the one or more first support structures 410b of the first non-active gate structure 802a may be facing toward the one or more fin structures 206, and/or the one or more second support structures 410b of the second non-active gate structure 802b may be facing toward the one or more second fin structures 206.

As further shown in FIG. 8A, in the example implementation 800, the first non-active gate structure 802a and the second non-active gate structure 802b may include a same quantity of support structures 410b (e.g., three support structures 410b). Moreover, the one or more first support structures 410b of the first non-active gate structure 802a and the one or more second support structures 410b of the second non-active gate structure 802b may be arranged in a symmetrical configuration in which each of the one or more first support structures 410b are aligned with an associated one of the one or more second support structures 410b along the second direction (e.g., the y direction). In other words, the arrangement of one or more first support structures 410b and the arrangement of the one or more second support structures 410b are mirrored about the second direction (e.g., y direction). Alternatively, a subset of the one or more first support structures 410b are aligned with an associated one of the one or more second support structures 410b along the second direction (e.g., the y direction).

FIG. 8B illustrates an example implementation 810 in which a first non-active gate structure 812a and a second non-active gate structure 812b may include a same quantity of support structures 410b (e.g., two support structures 410b). The first support structures 410b of the first non-active gate structure 812a may be located at opposing ends of the first main body 410a of the first non-active gate structure 812a. The second support structures 410b of the second non-active gate structure 812b may be located at opposing ends of the second main body 410a of the second non-active gate structure 812b.

The first support structures 410b of the first non-active gate structure 812a and the second support structures 410b of the second non-active gate structure 812b may be arranged in a symmetrical configuration in which each of the first support structures 410b are aligned with an associated one of the one or more second support structures 410b along the second direction (e.g., the y direction). Alternatively, a subset of the first support structures 410b are aligned with an associated one of the second support structures 410b along the second direction (e.g., the y direction).

FIG. 8C illustrates an example implementation 820 in which a first non-active gate structure 822a and a second non-active gate structure 822b may include a same quantity of support structures 410b (e.g., four support structures 410b). The first support structures 410b of the first non-active gate structure 822a and the second support structures 410b of the second non-active gate structure 822b may be arranged in a symmetrical configuration in which each of the first support structures 410b are aligned with an associated one of the one or more second support structures 410b along the second direction (e.g., the y direction). Additionally and/or alternatively, a subset of the first support structures 410b are aligned with an associated one of the second support structures 410b along the second direction (e.g., the y direction). Additionally and/or alternatively, two or more adjacent non-active gate structures in the semiconductor device 200 may include different quantities of support structures.

FIG. 8D illustrates an example implementation 830 in which a first non-active gate structure 832a and a second non-active gate structure 832b may include a same quantity of support structures 410b (e.g., two support structures 410b). The first support structures 410b of the first non-active gate structure 832a may be located inward toward a center of the first main body 410a of the first non-active gate structure 832a as opposed to being located at opposing ends of the first main body 410a in the example implementation 810. The second support structures 410b of the second non-active gate structure 832b may be located inward toward a center of the second main body 410a of the second non-active gate structure 832b as opposed to being located at opposing ends of the second main body 410a in the example implementation 810.

The first support structures 410b of the first non-active gate structure 832a and the second support structures 410b of the second non-active gate structure 832b may be arranged in a symmetrical configuration in which each of the first support structures 410b are aligned with an associated one of the one or more second support structures 410b along the second direction (e.g., the y direction). Alternatively, a subset of the first support structures 410b are aligned with an associated one of the second support structures 410b along the second direction (e.g., the y direction).

As indicated above, FIGS. 8A-8D are provided as an example. Other examples may differ from what is described with regard to FIGS. 8A-8D. For example, one or more of the non-active gate structures included in the semiconductor device 200 may include a different quantity of support structures and/or a different arrangement of support structures than those illustrated in the example implementations of FIGS. 8A-8D.

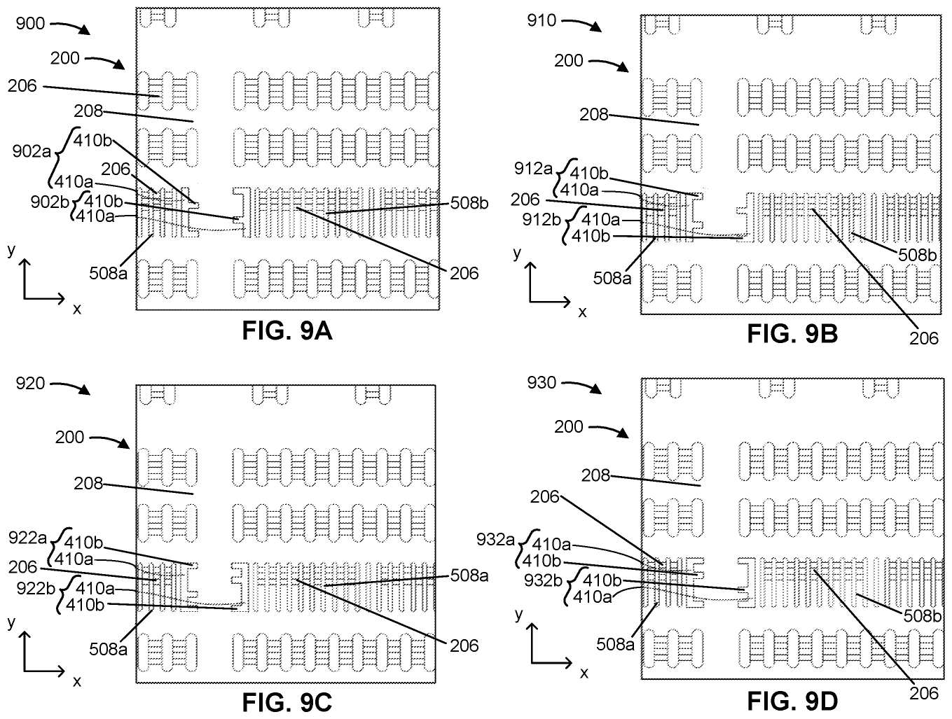

FIGS. 9A-9D are diagrams of example implementations of a semiconductor device described herein. FIGS. 9A-9D illustrate top-down views of the semiconductor device 200, in which example implementations of non-active gate structure configurations are illustrated. As described herein, the non-active gate structures may include one or more support structures that extend from a main body of the non-active gate structures. The example implementations of the semiconductor device 200 illustrated in FIGS. 9A-9D include various configurations of non-active gate structures in which support structures of adjacent non-active gate structures are offset and/or mirrored from one another.

FIG. 9A illustrates an example implementation 900 of the semiconductor device 200. The semiconductor device 200 may include one or more first fin structures 206 extending above a substrate, where the one or more first fin structures 206 extend in a first direction (e.g., an x direction) in the top-down view of the semiconductor device 200. The semiconductor device 200 may include one or more first active gate structure 508a that wrap around the one or more first fin structures 206 on at least three sides of the one or more first fin structures 206, where the one or more first active gate structures 508a extend in a second direction (e.g., the y direction), in the top-down view of the semiconductor device 200, that is approximately perpendicular with the first direction (e.g., the x direction).

As shown in FIG. 9A, the semiconductor device 200 may include a first non-active gate structure 902a (e.g., a non-active gate structure 508b) on an STI region 208, where the first non-active gate structure 902a is adjacent to ends of the one or more first fin structures 206. The first non-active gate structure 902a may include a first main body 410a that extends in the second direction (e.g., in the y direction) and one or more first support structures 410b that extend from the first main body 410a in the first direction (e.g., the x direction).

The semiconductor device 200 may include one or more second fin structures 206 extending above the substrate, where the one or more second fin structures 206 extend in the first direction (e.g., the x direction). The semiconductor device 200 may include one or more second active gate structures 508a that wrap around the one or more second fin structures 206 on at least three sides of the one or more second fin structures 206, where the one or more second active gate structures 508a extend in the second direction (e.g., in the y direction).

As shown in FIG. 9A, the semiconductor device 200 may include a second non-active gate structure 902b (e.g., a non-active gate structure 508b) on the STI region 208 and adjacent to the first non-active gate structure 902a. The second non-active gate structure 902b is adjacent to ends of the one or more second fin structures 206. The second non-active gate structure 902b may include a second main body 410a that extends in the second direction (e.g., the y direction) and one or more second support structures 410b that extend from the second main body 410a in the first direction (e.g., the x direction).

As further shown in FIG. 9A, the one or more first support structures 410b may extend from a side of the first main body 410a that is different from a side of the second main body 410a from which the one or more support structures 410b extend. In this way, the one or more first support structures 410b of the first non-active gate structure 902a and the one or more second support structures 410b of the second non-active gate structure 902b are facing each other. Thus, the one or more first fin structures 206 may be located on a first side of the first main body 410a of the first non-active gate structure 902a, and the one or more first support structures 410b may be located on a second side of the first main body 410a of the first non-active gate structure 902a, where the first side and the second side are opposing sides. In other words, the one or more first support structures 410b of the first non-active gate structure 902a may be facing away from the one or more first fin structures 206 and toward the second non-active gate structure 902b.

The one or more second fin structures 206 may be located on a first side of the second main body 410a of the second non-active gate structure 802b, and the one or more second support structures 410b may be located on a second side of the second main body 410a of the second non-active gate structure 902b, where the first side and the second side are opposing sides. In other words, the one or more second support structures 410b of the second non-active gate structure 902b may be facing away from the one or more second fin structures 206 and toward the first non-active gate structure 902a.

Alternatively, the one or more first support structures 410b and/or the one or more second support structures 410b may be arranged in a different configuration. For example, the one or more first support structures 410b of the first non-active gate structure 902a may be facing toward the one or more fin structures 206, and/or the one or more second support structures 410b of the second non-active gate structure 902b may be facing toward the one or more second fin structures 206.

As further shown in FIG. 9A, in the example implementation 900, the first non-active gate structure 902a and the second non-active gate structure 902b may include a same quantity of support structures 410b (e.g., two support structures 410b). Moreover, the one or more first support structures 410b of the first non-active gate structure 902a and the one or more second support structures 410b of the second non-active gate structure 902b may be arranged in an offset configuration in which each of the one or more first support structures 410b are offset from the one of the one or more second support structures 410b along the second direction (e.g., the y direction). In other words, each of the one or more first support structures 410b are not aligned with the one or more second support structures 410b along the second direction (e.g., the y direction). Alternatively, a subset of the one or more first support structures 410b may be offset from the one or more second support structures 410b along the second direction (e.g., the y direction). Additionally and/or alternatively, two or more adjacent non-active gate structures in the semiconductor device 200 may include different quantities of support structures.

As further shown in FIG. 9A, the arrangement of one or more first support structures 410b and the arrangement of the one or more second support structures 410b may be mirrored about the first direction (e.g., x direction). In other words, the arrangement of one or more first support structures 410b and the arrangement of the one or more second support structures 410b may be mirrored opposing arrangements about the first direction, where the arrangement of one or more first support structures 410b is flipped in the x direction relative to the arrangement of one or more second support structures 410b, and vice versa.

FIG. 9B illustrates an example implementation 910 in which a first non-active gate structure 912a and a second non-active gate structure 912b may include a same quantity of support structures 410b (e.g., two support structures 410b). As further shown in FIG. 9B, an arrangement of one or more first support structures 410b of the first non-active gate structure 912a, and the arrangement of one or more second support structures 410b of the second non-active gate structure 912b, may be mirrored about the first direction (e.g., x direction). In other words, the arrangement of one or more first support structures 410b and the arrangement of the one or more second support structures 410b may be mirrored opposing arrangements about the first direction, where the arrangement of one or more first support structures 410b is flipped in the x direction relative to the arrangement of one or more second support structures 410b, and vice versa.

Moreover, the one or more first support structures 410b of the first non-active gate structure 912a and the one or more second support structures 410b of the second non-active gate structure 912b may be arranged in an offset configuration in which each of the one or more first support structures 410b are offset from the one of the one or more second support structures 410b along the second direction (e.g., the y direction). In other words, each of the one or more first support structures 410b are not aligned with the one or more second support structures 410b along the second direction (e.g., the y direction). Alternatively, a subset of the one or more first support structures 410b may be offset from the one or more second support structures 410b along the second direction (e.g., the y direction).

FIG. 9C illustrates an example implementation 920 in which a first non-active gate structure 922a and a second non-active gate structure 922b may include a same quantity of support structures 410b (e.g., two support structures 410b). As further shown in FIG. 9C, an arrangement of one or more first support structures 410b of the first non-active gate structure 922a, and the arrangement of one or more second support structures 410b of the second non-active gate structure 922b, may be mirrored about the first direction (e.g., x direction). In other words, the arrangement of one or more first support structures 410b and the arrangement of the one or more second support structures 410b may be mirrored opposing arrangements about the first direction, where the arrangement of one or more first support structures 410b is flipped in the x direction relative to the arrangement of one or more second support structures 410b, and vice versa.

Moreover, a subset of the one or more first support structures 410b of the first non-active gate structure 922a and a subset of the one or more second support structures 410b of the second non-active gate structure 922b may be arranged in an offset configuration in which each of the subset of the one or more first support structures 410b are offset from the subset of the one or more second support structures 410b along the second direction (e.g., the y direction). Another subset of the one or more first support structures 410b may be aligned with another subset of the one or more second support structures 410b along the second direction (e.g., the y direction).

FIG. 9D illustrates an example implementation 930 in which a first non-active gate structure 932a and a second non-active gate structure 932b may include a same quantity of support structures 410b (e.g., two support structures 410b). As further shown in FIG. 9D, an arrangement of one or more first support structures 410b of the first non-active gate structure 932a, and the arrangement of one or more second support structures 410b of the second non-active gate structure 932b, may be mirrored about the first direction (e.g., x direction). In other words, the arrangement of one or more first support structures 410b and the arrangement of the one or more second support structures 410b may be mirrored opposing arrangements about the first direction, where the arrangement of one or more first support structures 410b is flipped in the x direction relative to the arrangement of one or more second support structures 410b, and vice versa.

Moreover, a subset of the one or more first support structures 410b of the first non-active gate structure 932a and a subset of the one or more second support structures 410b of the second non-active gate structure 932b may be arranged in an offset configuration in which each of the subset of the one or more first support structures 410b are offset from the subset of the one or more second support structures 410b along the second direction (e.g., the y direction). Another subset of the one or more first support structures 410b may be aligned with another subset of the one or more second support structures 410b along the second direction (e.g., the y direction).

As indicated above, FIGS. 9A-9D are provided as an example. Other examples may differ from what is described with regard to FIGS. 9A-9D. For example, one or more of the non-active gate structures included in the semiconductor device 200 may include a different quantity of support structures and/or a different arrangement of support structures than those illustrated in the example implementations of FIGS. 9A-9D.

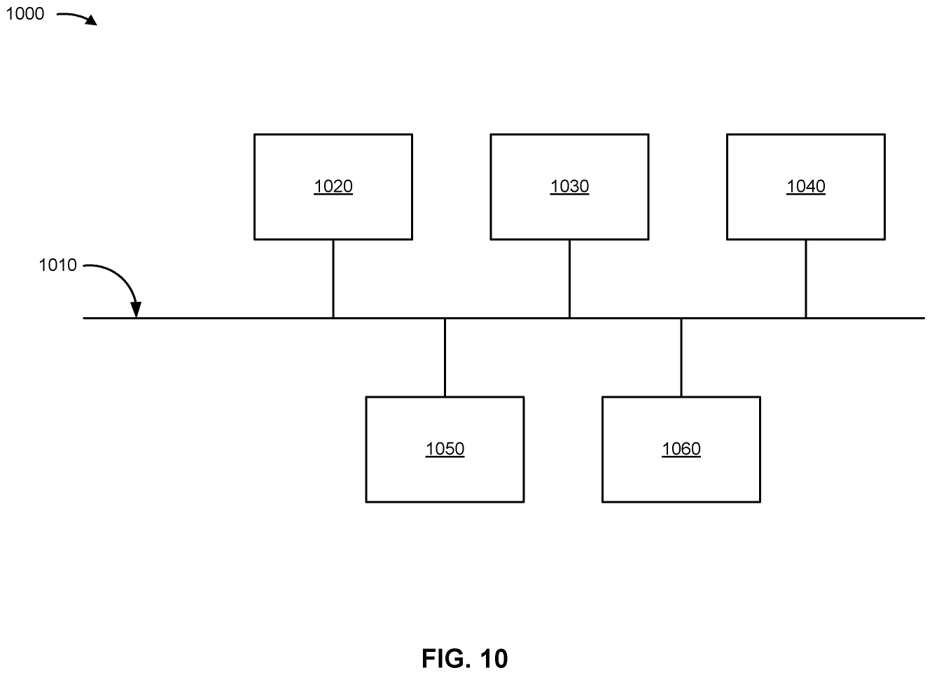

FIG. 10 is a diagram of example components of a device 1000 described herein. In some implementations, one or more of the semiconductor processing tools 102-112 and/or the wafer/die transport tool 114 may include one or more devices 1000 and/or one or more components of the device 1000. As shown in FIG. 10, the device 1000 may include a bus 1010, a processor 1020, a memory 1030, an input component 1040, an output component 1050, and/or a communication component 1060.

The bus 1010 may include one or more components that enable wired and/or wireless communication among the components of the device 1000. The bus 1010 may couple together two or more components of FIG. 10, such as via operative coupling, communicative coupling, electronic coupling, and/or electric coupling. For example, the bus 1010 may include an electrical connection (e.g., a wire, a trace, and/or a lead) and/or a wireless bus. The processor 1020 may include a central processing unit, a graphics processing unit, a microprocessor, a controller, a microcontroller, a digital signal processor, a field-programmable gate array, an application-specific integrated circuit, and/or another type of processing component. The processor 1020 may be implemented in hardware, firmware, or a combination of hardware and software. In some implementations, the processor 1020 may include one or more processors capable of being programmed to perform one or more operations or processes described elsewhere herein.

The memory 1030 may include volatile and/or nonvolatile memory. For example, the memory 1030 may include random access memory (RAM), read only memory (ROM), a hard disk drive, and/or another type of memory (e.g., a flash memory, a magnetic memory, and/or an optical memory). The memory 1030 may include internal memory (e.g., RAM, ROM, or a hard disk drive) and/or removable memory (e.g., removable via a universal serial bus connection). The memory 1030 may be a non-transitory computer-readable medium. The memory 1030 may store information, one or more instructions, and/or software (e.g., one or more software applications) related to the operation of the device 1000. In some implementations, the memory 1030 may include one or more memories that are coupled (e.g., communicatively coupled) to one or more processors (e.g., processor 1020), such as via the bus 1010. Communicative coupling between a processor 1020 and a memory 1030 may enable the processor 1020 to read and/or process information stored in the memory 1030 and/or to store information in the memory 1030.

The input component 1040 may enable the device 1000 to receive input, such as user input and/or sensed input. For example, the input component 1040 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1050 may enable the device 1000 to provide output, such as via a display, a speaker, and/or a light-emitting diode. The communication component 1060 may enable the device 1000 to communicate with other devices via a wired connection and/or a wireless connection. For example, the communication component 1060 may include a receiver, a transmitter, a transceiver, a modem, a network interface card, and/or an antenna.

The device 1000 may perform one or more operations or processes described herein. For example, a non-transitory computer-readable medium (e.g., memory 1030) may store a set of instructions (e.g., one or more instructions or code) for execution by the processor 1020. The processor 1020 may execute the set of instructions to perform one or more operations or processes described herein. In some implementations, execution of the set of instructions, by one or more processors 1020, causes the one or more processors 1020 and/or the device 1000 to perform one or more operations or processes described herein. In some implementations, hardwired circuitry may be used instead of or in combination with the instructions to perform one or more operations or processes described herein. Additionally, or alternatively, the processor 1020 may be configured to perform one or more operations or processes described herein. Thus, implementations described herein are not limited to any specific combination of hardware circuitry and software.

The number and arrangement of components shown in FIG. 10 are provided as an example. The device 1000 may include additional components, fewer components, different components, or differently arranged components than those shown in FIG. 10. Additionally, or alternatively, a set of components (e.g., one or more components) of the device 1000 may perform one or more functions described as being performed by another set of components of the device 1000.

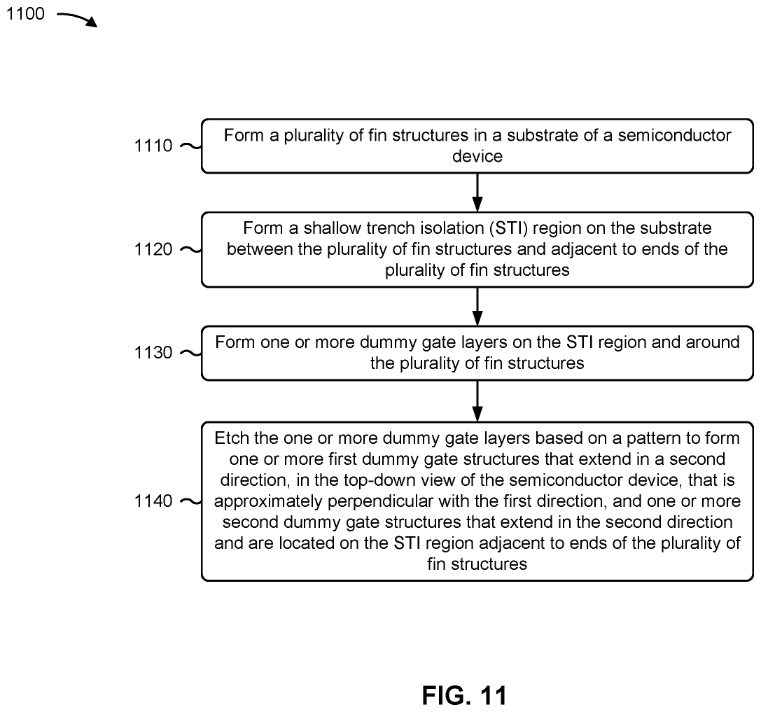

FIG. 11 is a flowchart of an example process 1100 associated with forming a semiconductor device. In some implementations, one or more process blocks of FIG. 11 are performed by one or more semiconductor processing tools (e.g., one or more of the semiconductor processing tools 102-112). Additionally, or alternatively, one or more process blocks of FIG. 11 may be performed by one or more components of device 1000, such as processor 1020, memory 1030, input component 1040, output component 1050, and/or communication component 1060.

As shown in FIG. 11, process 1100 may include forming a plurality of fin structures in a substrate of a semiconductor device (block 1110). For example, one or more of the semiconductor processing tools 102-112 may form a plurality of fin structures 206 in a substrate 204 of a semiconductor device 200, as described herein. In some implementations, the plurality of fin structures 206 extend in a first direction (e.g., an x direction) in a top-down view of the semiconductor device.

As further shown in FIG. 11, process 1100 may include forming an STI region on the substrate between the plurality of fin structures and adjacent to ends of the plurality of fin structures (block 1120). For example, one or more of the semiconductor processing tools 102-112 may form an STI region 208 on the substrate 204 between the plurality of fin structures 206 and adjacent to ends of the plurality of fin structures 206, as described herein. In some implementations, the plurality of fin structures extend above the STI region.

As further shown in FIG. 11, process 1100 may include forming one or more dummy gate layers on the STI region and around the plurality of fin structures (block 1130). For example, one or more of the semiconductor processing tools 102-112 may form one or more dummy gate layers (e.g., layers 402-406) on the STI region 208 and around the plurality of fin structures 206, as described herein.

As further shown in FIG. 11, process 1100 may include etching the one or more dummy gate layers based on a pattern to form one or more first dummy gate structures that extend in a second direction, in the top-down view of the semiconductor device, that is approximately perpendicular with the first direction, and one or more second dummy gate structures that extend in the second direction and are located on the STI region adjacent to ends of the plurality of fin structures (block 1140). For example, one or more of the semiconductor processing tools 102-112 may etch the one or more dummy gate layers based on a pattern to form one or more first dummy gate structures 210a that extend in a second direction (e.g., a y direction), in the top-down view of the semiconductor device 200, that is approximately perpendicular with the first direction, and one or more second dummy gate structures 210b that extend in the second direction and are located on the STI region 208 adjacent to ends of the plurality of fin structures 206, as described herein. In some implementations, the one or more first dummy gate structures 210a wrap around the plurality of fin structures 206 on at least three sides of the plurality of fin structures 206. In some implementations, the one or more second dummy gate structures include a main body 410a that extends in the second direction, and one or more support structures 410b that extend from the main body 410a in the first direction.

Process 1100 may include additional implementations, such as any single implementation or any combination of implementations described below and/or in connection with one or more other processes described elsewhere herein.

In a first implementation, process 1100 includes performing a wet cleaning operation after etching the one or more dummy gate layers, where the one or more support structures 410b support the one or more second dummy gate structures 210b during the wet cleaning operation.

In a second implementation, alone or in combination with the first implementation, process 1100 includes performing a wet cleaning operation after etching the one or more dummy gate layers, where the one or more second dummy gate structures 210b protect the one or more first dummy gate structures 210a during the wet cleaning operation.

In a third implementation, alone or in combination with one or more of the first and second implementations, process 1100 includes forming, after etching the one or more dummy gate layers, one or more source/drain regions 418 on one or more of the plurality of fin structures 206, and removing, after forming the one or more source/drain regions 418, the one or more first dummy gate structures 210a and the one or more second dummy gate structures 210b, where removal of the one or more first dummy gate structures 210a leaves behind one or more first recesses 506a over the plurality of fins 206, and where removal of the one or more second dummy gate structures 210b leaves behind one or more second recesses 506b over the STI region 208.

In a fourth implementation, alone or in combination with one or more of the first through third implementations, process 1100 includes forming, in the one or more first recesses 506a, one or more active gate structures 508a, and forming, in the one or more second recesses 506b, one or more non-active gate structures 508b.

In a fifth implementation, alone or in combination with one or more of the first through fourth implementations, process 1100 includes forming one or more spacer layers (e.g., seal spacer layers 412, bulk spacer layers 414) on sidewalls of the one or more support structures 410b.

In a sixth implementation, alone or in combination with one or more of the first through fifth implementations, the ends of the plurality of fin structures 206 are adjacent to a first side of the main body 410a, and the one or more support structures 410b extend from a second side of the main body 410a opposing the first side.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a non-active gate structure is formed over an STI region that is adjacent to at least one fin structure of a semiconductor device that includes a fin-based transistor. The non-active gate structure includes at least one support structure that extends from the gate in a direction that is approximately orthogonal to the direction in which the main body of the non-active gate structure extends. The support structure provides structural support for the non-active gate structure, which increases the stability of the non-active gate structure relative to a gate structure that does not include the support structure.

As described in greater detail above, some implementations described herein provide a semiconductor device. The semiconductor device includes one or more fin structures extending above a substrate, where the one or more fin structures extend in a first direction in a top-down view of the semiconductor device. The semiconductor device includes an active gate structure that wraps around the one or more fin structures on at least three sides of the one or more fin structures, where the active gate structure extends in a second direction, in the top-down view of the semiconductor device, that is approximately perpendicular with the first direction. The semiconductor device includes a non-active gate structure on an STI region, where the non-active gate structure is adjacent to ends of the one or more fin structures, and where the non-active gate structure includes a main body that extends in the second direction and one or more support structures that extend from the main body in the first direction.

As described in greater detail above, some implementations described herein provide a method. The method includes forming a plurality of fin structures in a substrate of a semiconductor device, where the plurality of fin structures extend in a first direction in a top-down view of the semiconductor device. The method includes forming an STI region on the substrate between the plurality of fin structures and adjacent to ends of the plurality of fin structures, where the plurality of fin structures extend above the STI region. The method includes forming one or more dummy gate layers on the STI region and around the plurality of fin structures. The method includes etching the one or more dummy gate layers based on a pattern to form one or more first dummy gate structures that extend in a second direction, in the top-down view of the semiconductor device, that is approximately perpendicular with the first direction, where the one or more first dummy gate structures wrap around the plurality of fin structures on at least three sides of the plurality of fin structures. The method includes etching the one or more dummy gate layers based on a pattern to form one or more second dummy gate structures that extend in the second direction and are located on the STI region adjacent to ends of the plurality of fin structures, where the one or more second dummy gate structures include a main body that extends in the second direction, and one or more support structures that extend from the main body in the first direction.

As described in greater detail above, some implementations described herein provide a semiconductor device. The semiconductor device includes one or more first fin structures extending above a substrate, where the one or more first fin structures extend in a first direction in a top-down view of the semiconductor device. The semiconductor device includes a first active gate structure that wraps around the one or more first fin structures on at least three sides of the one or more first fin structures, where the first active gate structure extends in a second direction, in the top-down view of the semiconductor device, that is approximately perpendicular with the first direction. The semiconductor device includes a first non-active gate structure on an STI region, where the first non-active gate structure is adjacent to ends of the one or more first fin structures, and where the first non-active gate structure comprises: a first main body that extends in the second direction one or more first support structures that extend from the first main body in the first direction. The semiconductor device includes one or more second fin structures extending above the substrate, where the one or more second fin structures extend in the first direction. The semiconductor device includes a second active gate structure that wraps around the one or more second fin structures on at least three sides of the one or more second fin structures, where the second active gate structure extends in the second direction. The semiconductor device includes a second non-active gate structure on the STI region and adjacent to the first non-active gate structure, where the second non-active gate structure is adjacent to ends of the one or more second fin structures, and where the second non-active gate structure comprises: a second main body that extends in the second direction one or more second support structures that extend from the second main body in the first direction.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more fin structures extending above a substrate,
wherein the one or more fin structures extend in a first direction in a top-down view of the semiconductor device;
an active gate structure that wraps around the one or more fin structures on at least three sides of the one or more fin structures,
wherein the active gate structure extends in a second direction, in the top-down view of the semiconductor device, that is approximately perpendicular with the first direction; and
a non-active gate structure on a shallow trench isolation (STI) region,
wherein the non-active gate structure is adjacent to ends of the one or more fin structures, and
wherein the non-active gate structure comprises:
a main body that extends in the second direction; and
one or more support structures that extend from the main body in the first direction.

2. The semiconductor device of claim 1, wherein the ends of the one or more fin structures are adjacent to a first side of the main body; and
wherein the one or more support structures extend from a second side of the main body opposing the first side.

3. The semiconductor device of claim 1, wherein a distance between one or more support structures and another active structure in the semiconductor device satisfies a distance threshold; and
wherein the distance threshold is at least two times a size of an active gate structure pitch of the semiconductor device.

4. The semiconductor device of claim 1, wherein the one or more fin structures comprise a first plurality of fin structures that are included in a first fin group;
wherein the active gate structure comprises a first active gate structure that extends across the first fin group;
wherein the non-active gate structure comprises a first non-active gate structure that extends alongside the first active gate structure; and
wherein the semiconductor device further comprises:
a second plurality of fin structures, included in a second fin group adjacent to the first fin group, that extends in the first direction;
a second active gate structure that extends across the second fin group in the second direction and wraps around at least three sides of the second plurality of fin structures; and
a second non-active gate structure adjacent to ends of the plurality of second fin structures and extending alongside the second active gate structure,
wherein the second non-active gate structure comprises:
a main body that extends in the second direction; and
one or more support structures that extend from the main body of the second non-active gate structure in the first direction.

5. The semiconductor device of claim 1, wherein a width of a support structure, of the one or more support structures, in the second direction is included in a range of approximately 1.5 times to approximately 2.5 times a length of the main body in the first direction.

6. The semiconductor device of claim 1, wherein the one or more fin structures comprise a first plurality of fin structures that are included in a first fin group;
wherein the active gate structure comprises a first active gate structure that extends across the first fin group; and
wherein the semiconductor device further comprises:
a second plurality of fin structures, included in a second fin group adjacent to the first fin group, that extends in the first direction; and
a second active gate structure that extends across the second fin group in the second direction,
wherein the non-active gate structure continuously extends alongside the first active gate structure and the second active gate structure and spans the first fin group and the second fin group.

7. The semiconductor device of claim 1, wherein a length of a support structure, of the one or more support structures, in the first direction is included in a range of approximately 1.5 times to approximately 2.5 times a length of the main body in the first direction.

8. A method, comprising:
forming a plurality of fin structures in a substrate of a semiconductor device,
wherein the plurality of fin structures extend in a first direction in a top-down view of the semiconductor device;
forming a shallow trench isolation (STI) region on the substrate between the plurality of fin structures and adjacent to ends of the plurality of fin structures,
wherein the plurality of fin structures extend above the STI region;
forming one or more dummy gate layers on the STI region and around the plurality of fin structures;
etching the one or more dummy gate layers based on a pattern to form:
one or more first dummy gate structures that extend in a second direction, in the top-down view of the semiconductor device, that is approximately perpendicular with the first direction,
wherein the one or more first dummy gate structures wrap around the plurality of fin structures on at least three sides of the plurality of fin structures; and
one or more second dummy gate structures that extend in the second direction and are located on the STI region adjacent to ends of the plurality of fin structures,
wherein the one or more second dummy gate structures comprise:
a main body that extends in the second direction; and
one or more support structures that extend from the main body in the first direction.

9. The method of claim 8, further comprising:
performing a wet cleaning operation after etching the one or more dummy gate layers,
wherein the one or more support structures support the one or more second dummy gate structures during the wet cleaning operation.

10. The method of claim 8, further comprising:
performing a wet cleaning operation after etching the one or more dummy gate layers,
wherein the one or more second dummy gate structures protect the one or more first dummy gate structures during the wet cleaning operation.

11. The method of claim 8, further comprising:
forming, after etching the one or more dummy gate layers, one or more source/drain regions on one or more of the plurality of fin structures; and
removing, after forming the one or more source/drain regions, the one or more first dummy gate structures and the one or more second dummy gate structures,
wherein removal of the one or more first dummy gate structures leaves behind one or more first recesses over the plurality of fin structures, and
wherein removal of the one or more second dummy gate structures leaves behind one or more second recesses over the STI region.

12. The method of claim 11, further comprising:
forming, in the one or more first recesses, one or more active gate structures; and
forming, in the one or more second recesses, one or more non-active gate structures.

13. The method of claim 8, further comprising:
forming one or more spacer layers on sidewalls of the one or more support structures.

14. The method of claim 8, wherein the ends of the plurality of fin structures are adjacent to a first side of the main body; and
wherein the one or more support structures extend from a second side of the main body opposing the first side.

15. A semiconductor device, comprising:
one or more first fin structures extending above a substrate,
wherein the one or more first fin structures extend in a first direction in a top-down view of the semiconductor device;
a first active gate structure that wraps around the one or more first fin structures on at least three sides of the one or more first fin structures,
wherein the first active gate structure extends in a second direction, in the top-down view of the semiconductor device, that is approximately perpendicular with the first direction; and
a first non-active gate structure on a shallow trench isolation (STI) region,
wherein the first non-active gate structure is adjacent to ends of the one or more first fin structures, and
wherein the first non-active gate structure comprises:
a first main body that extends in the second direction; and
one or more first support structures that extend from the first main body in the first direction;
one or more second fin structures extending above the substrate,
wherein the one or more second fin structures extend in the first direction;
a second active gate structure that wraps around the one or more second fin structures on at least three sides of the one or more second fin structures,
wherein the second active gate structure extends in the second direction; and
a second non-active gate structure on the STI region and adjacent to the first non-active gate structure,
wherein the second non-active gate structure is adjacent to ends of the one or more second fin structures, and
wherein the second non-active gate structure comprises:
a second main body that extends in the second direction; and
one or more second support structures that extend from the second main body in the first direction.

16. The semiconductor device of claim 15, wherein a quantity of the one or more first support structures and a quantity of the one or more second support structures are a same quantity of support structures.

17. The semiconductor device of claim 15, wherein a quantity of the one or more first support structures and a quantity of the one or more second support structures are different quantities of support structures.

18. The semiconductor device of claim 15, wherein each of the one or more first support structures are aligned with an associated one of the one or more second support structures along the second direction.

19. The semiconductor device of claim 15, wherein each of the one or more first support structures are offset from the one of the one or more second support structures along the second direction.

20. The semiconductor device of claim 15, wherein an arrangement of the one or more first support structures and an arrangement of the one or more second support structures are mirrored about at least one of the first direction or the second direction.
